(19) United States
(12) Patent Application Publication
(10) Pub. No.: US 2025/0301866 A1
(43) Pub. Date: Sep. 25, 2025

(54) DISPLAY PANEL AND DISPLAY APPARATUS

(71) Applicants: Hefei Visionox Technology Co., Ltd., Hefei (CN); Visionox Technology Inc., Kunshan (CN)

(72) Inventors: Xiaoxi SUN, Hefei (CN); Yongqiang DU, Hefei (CN); Xuejing ZHU, Hefei (CN); Yuan YAO, Hefei (CN); Bo RAO, Hefei (CN); Xiujian ZHU, Hefei (CN)

(73) Assignees: Hefei Visionox Technology Co., Ltd., Hefei (CN); Visionox Technology Inc., Kunshan (CN)

(21) Appl. No.: 18/883,858

(22) Filed: Sep. 12, 2024

(30) Foreign Application Priority Data
Mar. 25, 2024 (CN) 202410342963.3

(51) Int. Cl. H10K 59/131; H10K 59/126; H10K 59/65

(52) U.S. Cl. CPC H10K 59/131; H10K 59/126; H10K 59/65

(57) ABSTRACT

The present application discloses a display panel and a display apparatus. The display panel includes a first display region. The first display region includes a first region. The display panel includes: a substrate and a plurality of wires located on the substrate. The first region includes at least one wire region, and the plurality of wires in the at least one wire region are stacked and insulated along a direction perpendicular to the substrate. According to the display panel provided in the present application, since the wires in the wire region are stacked along the direction perpendicular to the substrate, orthographic projections of the wires in the wire region on the substrate at least partially overlap, making an orthographic projection area of the wire region on the substrate smaller.

### CROSS REFERENCE TO RELATED APPLICATION

The present application claims priority to Chinese Patent Application No. 202410342963.3 filed on Mar. 25, 2024, and titled “DISPLAY PANEL AND DISPLAY APPARATUS”, which is incorporated herein by reference in its entirety.

### TECHNICAL FIELD

The present application belongs to the technical field of display, and in particular to a display panel and a display apparatus.

### BACKGROUND

With the development of a display technology, requirements for performance of a display panel are getting higher and higher, but the conventional display panel has low light transmittance, which affects an operational yield of a photosensitive module, thereby affecting the performance of the display panel.

### SUMMARY

Embodiments of the present application provide a display panel and a display apparatus, which can increase light transmittance of the display panel.

In a first aspect of the embodiments of the present application, an embodiment provides a display panel, including a first display region, the first display region includes a first region, and the display panel includes: a substrate and a plurality of wires located on the substrate; the first region includes at least one wire region, the at least one wire region includes at least part of the substrate and at least two of the plurality of wires located on the substrate, the at least two of the plurality of wires in the at least one wire region are stacked and insulated along a direction perpendicular to the substrate.

An embodiment in a second aspect further provides a display panel, wherein the display panel includes a first display region, the first display region includes a first region, and the display panel includes:
a substrate and a plurality of wires located on the substrate; wherein the first region includes at least one wire region, the at least one wire region includes at least part of the substrate and at least two of the plurality of wires located on the substrate, the at least two of the plurality of wires in the at least one wire region are stacked and insulated along a direction perpendicular to the substrate; the plurality of wires includes a first power signal line and at least one of a data line, a scan signal line, a reset signal line, a light-emitting signal line, and a second power signal line;
an isolation structure, wherein at least part of the isolation structure is reused as the first power signal line; in the at least one wire region, the at least part of the isolation structure reused as the first power signal line and the at least one of the data line, the scan signal line, the reset signal line, the light-emitting signal line, and the second power signal line are stacked and insulated along the direction perpendicular to the substrate.

An embodiment in a third aspect further provides a display apparatus, including any of the display panels provided in the first aspect of the present application.

According to the display panel provided in the present application, since the wires in the wire region are stacked along the direction perpendicular to the substrate, orthographic projections of the wires in the wire region on the substrate at least partially overlap, making an orthographic projection area of the wire region on the substrate smaller. Then, an area of a portion of the display panel that is not blocked by the wire region can be increased, thereby increasing light transmittance of the display panel.

### BRIEF DESCRIPTION OF THE DRAWINGS

FIG. 1 is a schematic top structural diagram of a display panel according to an embodiment of the present application;

FIG. 2 is a sectional view taken along P-P′ in FIG. 1;

FIG. 3 is a partial structural enlarged view of a region N in FIG. 1;

FIG. 4 is a partial structural enlarged view of another display panel according to an embodiment of the present application;

FIG. 5 is a schematic top structural diagram of another display panel according to an embodiment of the present application;

FIG. 6 is a sectional view taken along Q-Q′ in FIG. 3;

FIG. 7A to FIG. 7F are sectional views taken along M-M′ in FIG. 3 corresponding to a plurality of display panels according to embodiments of the present application;

FIG. 8 is a sectional view of another display panel at a first wire region according to an embodiment of the present application;

FIG. 9 is a sectional view of another display panel at a second wire region according to an embodiment of the present application;

FIG. 10 is a schematic diagram of a pixel circuit of another display panel according to an embodiment of the present application;

FIG. 11 is a partial structural enlarged view of another display panel according to an embodiment of the present application;

FIG. 12 is a sectional view of another display panel at a first wire region according to an embodiment of the present application;

FIG. 13 is a sectional view of another display panel at a second wire region according to an embodiment of the present application;

FIG. 14A to FIG. 14B are sectional views of a plurality of display panels at a second wire region according to embodiments of the present application;

FIG. 15 is a schematic diagram of a pixel circuit of another display panel according to an embodiment of the present application;

FIG. 16 is a partial sectional view of another display panel according to an embodiment of the present application; and

FIG. 17 is a schematic structural diagram of a display apparatus according to an embodiment of the present application.

In the drawings,

1: display panel; 10: substrate; 11: pixel circuit layer; 111: drive circuit region; 112: first wire region; 113: second wire region; 114: first conductive layer; 115: second conductive layer; 116: third conductive layer; 117: fourth conductive layer; 118: fifth conductive layer; 119: sixth conductive layer; 121: seventh conductive layer; 110: wire; Data: data line; Scan: scan signal line; Vref: reset signal line; EM: light-emitting signal line; ELVSS: first power signal line; ELVDD: second power signal line; Data 1: first data line; Data 2: second data line; Data 3: third data line; Data 4: fourth data line; 1101: first-type scan signal line; 1102: second-type scan signal line; Scan 1: first sub-scan line; Scan 2: second sub-scan line; Scan 3: third sub-scan line; Scan 4: fourth sub-scan line; 12: light-emitting layer; 120: repeating unit; 1201: first light-emitting unit; 1202: second light-emitting unit; 1203: third light-emitting unit; 1204: fourth light-emitting unit; x: first direction; y: second direction; z: thickness direction; 2: display apparatus; AA1: first display region; AA2: second display region; A1: first region; A2: second region; G: isolation structure; G1: first isolation portion; G2: second isolation portion; G3: third isolation portion.

### DETAILED DESCRIPTION

It is to be noted that, herein, the relationship terms such as first and second are only used to distinguish one entity or operation from another entity or operation, but do not necessarily require or imply that there is such an actual relationship or order between these entities or operations. Moreover, the terms “include,” “comprise,” or any other variants thereof are intended to cover a non-exclusive inclusion, such that processes, methods, articles, or devices including a series of elements include not only those elements that have been listed, but also other elements that have not specifically been listed or the elements intrinsic to these processes, methods, articles, or devices. Without more limitations, elements limited by the wording “comprise(s)/include(s) . . . ” do not exclude additional identical elements in the processes, methods, articles, or devices including the listed elements.

The inventor has found, after research, that the low transmittance of the display panel is due to the following reasons: the display panel includes drive circuits, and adjacent drive circuits are connected to each other by wires, but the wires involves a wider region, so the wires block light, making the light transmittance of the display panel low. Based on the research on the above problems, the inventor provides a display panel and a display apparatus, to increase the light transmittance of the display panel.

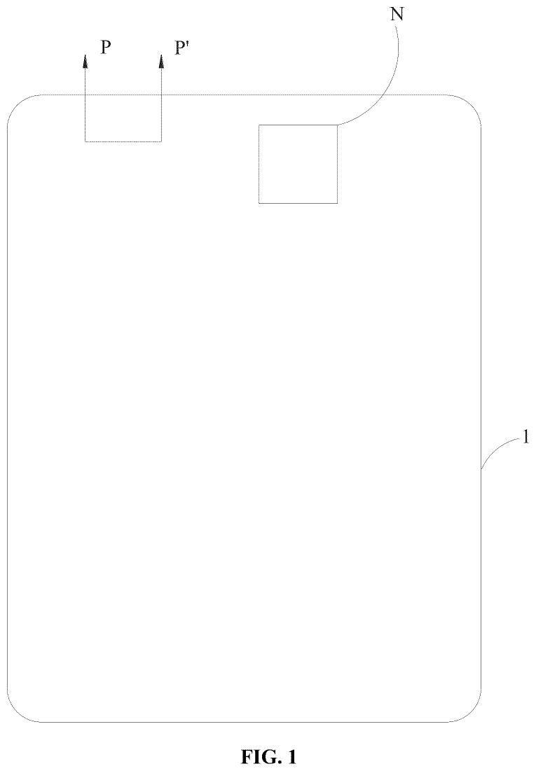

In order to better understand the present application, the display panel and the display apparatus according to the embodiments of the present application will be described in detail below with reference to FIG. 1 to FIG. 17.

In a first aspect, an embodiment of the present application provides a display panel 1. The display panel 1 has a first display region AA1. The first display region AA1 includes a first region A1. The display panel includes a substrate 10 and a plurality of wires 110 located on the substrate 10. The first region Al includes at least one wire region. The at least one wire region includes at least part of the substrate 10 and at least two of the plurality of wires 110 located on the substrate 10, the at least two of the plurality of wires 110 in the at least one wire region are stacked and insulated along a direction perpendicular to the substrate 10.

In the display panel 1 provided in the present application, the display panel 1 may be a transparent display panel 1. That is, the display panel 1 has only one type of display regions: the first display region AA1. Alternatively, the display panel 1 includes two types of display regions: a first display region AA1 and a second display region AA2. Light transmittance of the first display region AA1 is higher than light transmittance of the second display region AA2. A photosensitive module such as a camera module or a fingerprint recognition module may be arranged below the first display region AA1 (that is, a region corresponding to the photosensitive module). The light transmittance of the first display region AA1 is higher, which can improve performance of the photosensitive module, thereby improving performance of the display panel 1.

The display panel 1 includes a plurality of film structures that are stacked. Specific film composition in the display panel 1 is not limited in the embodiments of the present application. The display panel includes at least a substrate 10 and a plurality of wires 110 located on the substrate 10. The first display region AA1 includes a first region A1. The first region A1 includes at least one wire region. The at least one wire region includes at least part of the substrate 10 and at least two of the plurality of wires 110 located on the substrate 10, the at least two of the plurality of wires 110 in the at least one wire region are stacked along the direction perpendicular to the substrate 10, to increase light transmittance of the display panel 1.

Specifically, since the wires 110 in the wire region are stacked along the direction perpendicular to the substrate 10, orthographic projections of the plurality of wires 110 in the wire region on the substrate 10 at least partially overlap, making an orthographic projection area of the wire region on the substrate 10 smaller. Then, an area of a portion of the display panel 1 that is not blocked by the wire region can be increased, thereby increasing the light transmittance of the display panel 1.

In some embodiments, the first display region AA1 further includes at least one second region A2, and light transmittance of the first region A1 is lower than light transmittance of the second region A2; and/or the at least one wire region includes at least one first wire region 112, at least two of the plurality of wires 110 in the first wire region 112 are stacked along the direction perpendicular to the substrate 10, and the at least two of the plurality of wires in the first wire region 112 extend along a first direction x; and/or, the at least one wire region includes at least one second wire region 113, at least two of the plurality of wires 110 in the second wire region 113 are stacked along the direction perpendicular to the substrate 10, and the at least two of the plurality of wires in the second wire region 113 extend along a second direction y.

The first display region AA1 includes at least the first region A1 and the second region A2, the wires are arranged in the first region A1, at least one wire region is provided, and the wires arranged in the second region A2 are reduced or canceled, so that the light transmittance of the first region A1 is lower than the light transmittance of the second region A2. Since the light transmittance of the second region A2 is higher, the photosensitive module arranged on one side of the first display region AA1 may collect or receive light passing through the second region A2. The photosensitive module may be, for example, a camera module, a fingerprint recognition module, or the like. Further optionally, the second region A2 is a non-light-emitting region, to reduce an influence of light-emitting units on the light transmittance of the second region A2, which helps improve performance accuracy of the photosensitive module.

The first wire region 112 and the second wire region 113 each include a plurality of wires 110. On this basis, the wires 110 in the first wire region 112 may be stacked along the direction perpendicular to the substrate 10, so that orthographic projections of the wires 110 in the first wire region 112 on the substrate 10 at least partially overlap, making an orthographic projection area of the first wire region 112 on the substrate 10 smaller. Similarly, the wires 110 in the second wire region 113 may be stacked along the direction perpendicular to the substrate 10, so that orthographic projections of the wires 110 in the second wire region 113 on the substrate 10 at least partially overlap, making an orthographic projection area of the second wire region 113 on the substrate 10 smaller. Then, an area of a portion of the display panel 1 that is not blocked by the first wire region 112 and the second wire region 113 can be increased, that is, an area of the second region A2 is increased, thereby increasing the light transmittance of the display panel 1.

In some embodiments, the first region Al further includes at least one light-emitting region (which may be, for example, positioned the same as a drive circuit region 111 in FIG. 3). The at least one light-emitting region include a plurality of light-emitting regions. The at least one first wire region 112 includes a plurality of first wire regions 112, and the plurality of light-emitting regions and the plurality of first wire regions 112 are arranged alternately in the first direction x; and/or, the at least one second wire region includes a plurality of second wire regions 113, the plurality of light-emitting regions and the plurality of second wire regions 113 are arranged alternately in the second direction y. The first direction x intersects, for example, is perpendicular to, the second direction.

Light-emitting units may be arranged in the light-emitting region to realize a light-emitting display function. “The plurality of light-emitting regions and the plurality of first wire regions 112 are arranged alternately in the first direction x” means that two first wire regions 112 are arranged respectively on two sides of the light-emitting region in the first direction x. Further, a drive circuit configured to drive the light-emitting units to emit light and display may be correspondingly arranged at the light-emitting region, and the wires 110 in the first wire regions 112 may be electrically connected to the drive circuit, to meet light-emitting requirements of the light-emitting units.

Similarly, “the plurality of light-emitting regions and the plurality of second wire regions 113 are arranged alternately in the second direction y” means that two second wire regions 113 are arranged respectively on two sides of the light-emitting region in the second direction y. Further, a drive circuit configured to drive the light-emitting units to emit light and display may be correspondingly arranged at the light-emitting region, and the wires 110 in the second wire regions 113 may be electrically connected to the drive circuit, to meet light-emitting requirements of the light-emitting units.

In some embodiments, one or more of the first wire region 112, the second wire region 113, and the light-emitting region are arranged between adjacent second regions A2.

Referring to the drawings, the first wire region 112, the second wire region 113, and the light-emitting region may be enclosed to form a ring-shaped structure surrounding the second region A2. Further optionally, the at least one second region A2 includes a plurality of second regions A2, the plurality of second regions A2 and the plurality of first wire regions 112 are arranged alternately in the second direction y, and/or, the plurality of second regions A2 and the plurality of second wire regions 113 are arranged alternately in the first direction x.

This design enables adjacent first wire regions 112 to be spaced apart from each other by one second region A2, so as to alleviate the problem of degradation in a display effect caused by an excessively short distance between the adjacent first wire regions 112. Similarly, adjacent second wire regions 113 can be spaced apart from each other by one second region A2, so as to alleviate the problem of degradation in the display effect caused by an excessively short distance between the adjacent second wire regions 113.

In some embodiments, the plurality of wire include at least one shielded wire and a plurality of potential change signal lines, the first wire region 112 includes the at least one shielded wire and the plurality of potential change signal lines. The at least one shielded wire is arranged between the potential change signal lines in a direction z perpendicular to the substrate 10 (i.e., a thickness direction of the substrate). The at least one shielded wire includes a reset signal line Vref, or a power signal line, or the reset signal line Vref and the power signal line. The plurality of potential change signal lines include a scan signal line Scan, or a light-emitting signal line EM, or the scan signal line Scan and the light-emitting signal line EM.

At different moments, a signal voltage in the potential change signal line may change over time. That is, the potential change signal line is configured to transmit a variable-voltage signal. Unlike the potential change signal line, a signal voltage in the shielded wire does not change over time. That is, the shielded wire may be configured to transmit a constant-voltage signal. The shielded wire includes at least one of the reset signal line Vref and the power signal line. The power signal line includes a first power signal line ELVSS and a second power signal line ELVDD. The potential change signal line includes the scan signal line Scan, or the light-emitting signal line EM, or the scan signal line Scan and the light-emitting signal line EM.

The reset signal line Vref may be electrically connected to a reset transistor in a pixel circuit. The reset transistor may transmit a voltage on the reset signal line Vref to at least one of a gate, a source, and a drain of a drive transistor, and/or a first electrode of the light-emitting unit.

If no shielding blocking structure exists between different potential change signal lines arranged opposite to each other along the direction perpendicular to the substrate 10, coupling interference is likely to occur between the different potential change signal lines, affecting the normal use of the display panel 1.

In view of this, in the embodiments of the present application, layout of the wires 110 inside the display panel 1 is adjusted, and the shielded wire is arranged between the potential change signal lines along the direction perpendicular to the substrate 10. In this way, the shielded wire can produce an effect of signal shielding on different potential change signal lines arranged opposite to each other along the direction perpendicular to the substrate 10, reducing a risk of coupling interference between the different potential change signal lines and improving reliability of use of the display panel 1.

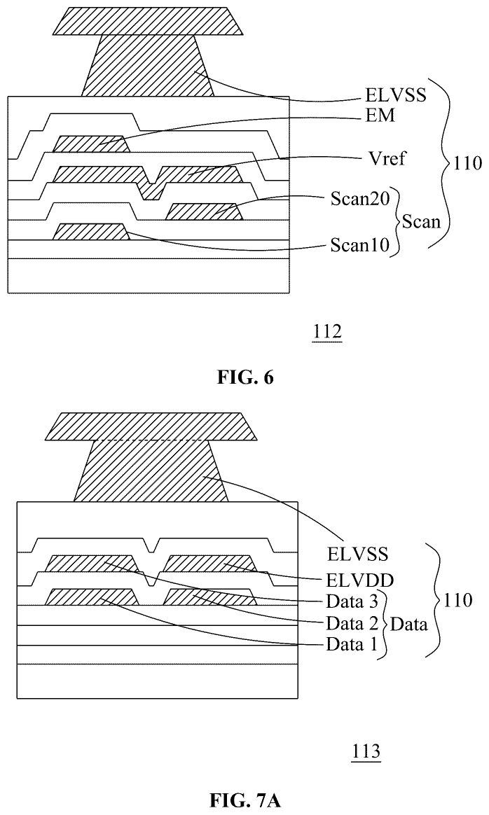

Specifically, optionally, as shown in FIG. 6, in the first wire region 112, the reset signal line Vref is arranged between the scan signal line Scan and the light-emitting signal line EM in the direction z perpendicular to the substrate 10. In this way, the reset signal line Vref can shield the scan signal line Scan and the light-emitting signal line EM, reducing a risk of signal coupling interference between the scan signal line Scan and the light-emitting signal line EM and improving reliability.

A plurality of scan signal lines Scan may be provided, and the plurality of scan signal lines Scan may be arranged in a same conductive layer. Alternatively, optionally, as shown in FIG. 6, in the first wire region 112, a plurality of scan signal lines Scan are located in at least two conductive layers. The plurality of scan signal lines Scan are arranged in different films so as to help increase spacings between different scan signal lines Scan, reducing interaction between the different scan signal lines Scan and improving reliability. An insulating layer may be arranged between the at least two conductive layers.

Optionally, as shown in FIG. 12, the plurality of wires include at least one second power signal line ELVDD, the first wire region 112 further includes the second power signal line ELVDD, and in the first wire region 112, the second power signal line ELVDD is arranged between the plurality of scan signal lines Scan along the direction perpendicular to the substrate 10. Further, in the first wire region 112, the second power signal line ELVDD is arranged between adjacent scan signal lines Scan along the direction perpendicular to the substrate 10. In this way, the second power signal line ELVDD can shield the plurality of scan signal lines Scan located in different conductive layers, reducing a risk of signal coupling interference between different scan signal lines Scan and improving reliability.

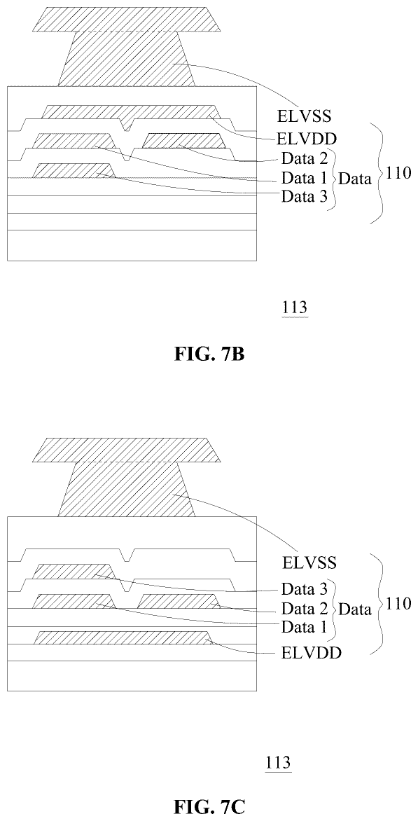

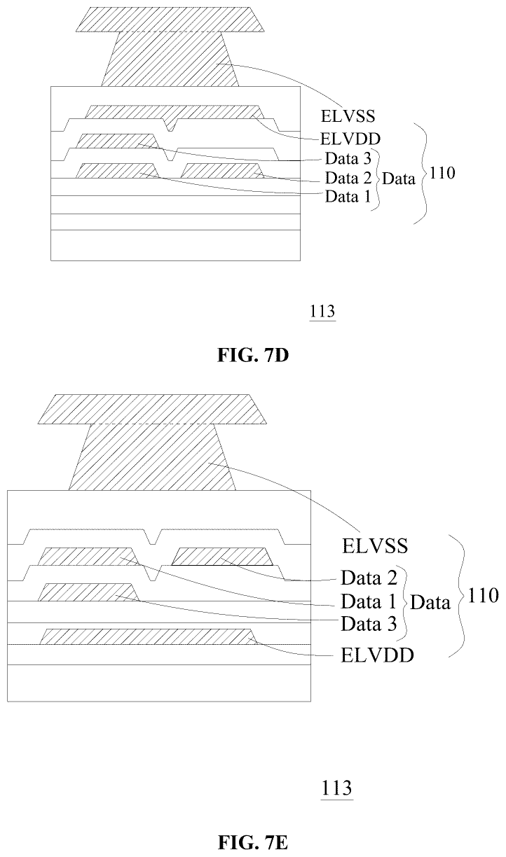

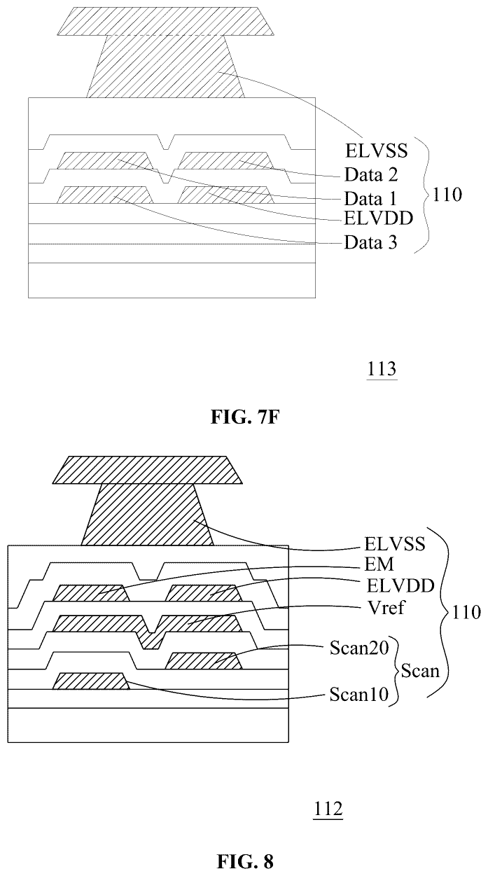

Optionally, as shown in FIG. 7A, the plurality of wires include a plurality of data lines Data, the second wire region 113 includes the plurality of data lines Data, and the plurality of data lines Data are located in at least two conductive layers. A plurality of data lines Data may also be provided. The plurality of data lines Data are arranged in different films so as to help increase spacings between different data lines Data, reducing interaction between the different data lines Data and improving reliability. Further optionally, the plurality of data lines Data in the second wire region 113 are stacked and insulated along the direction perpendicular to the substrate 10. An insulating layer may be arranged between the at least two conductive layers.

Optionally, the plurality of wires include at least one first power signal line ELVSS, the first wire region 112 includes the first power signal line ELVSS, the second wire region 113 includes the first power signal line ELVSS, and the first power signal line ELVSS in the first wire region 112 is electrically connected to the first power signal line ELVSS in the second wire region 113. In this way, the first power signal line ELVSS can form a structure in a mesh shape over an entire surface, so that resistance can be reduced.

Optionally, the first wire region 112 includes the second power signal line ELVDD, the second wire region 113 includes the second power signal line ELVDD, and the second power signal line ELVDD in the first wire region 112 is electrically connected to the second power signal line ELVDD in the second wire region 113. In this way, the second power signal line ELVDD can form a structure in a mesh shape over an entire surface, so that resistance can be reduced.

Referring to FIG. 1 to FIG. 4, in some embodiments, the display panel 1 includes a substrate 10, a pixel circuit layer 11, and a light-emitting layer 12. The pixel circuit layer 11 includes a drive circuit region 111, a first wire region 112, and a second wire region 113 located in the first region A1, the first wire region 112 and the second wire region 113 each include at least two of the plurality of wires 110, the at least two of the plurality of wires 110 in the first wire region 112 are stacked and insulated along the direction perpendicular to the substrate 10, and the at least two of the plurality of wires 110 in the second wire region 113 are stacked and insulated along the direction perpendicular to the substrate 10. The light-emitting layer 12 includes a plurality of light-emitting units located in the first region A1. For example, the light-emitting layer 12 includes a plurality of repeating units 120 located in the first region A1, the repeating unit 120 includes light-emitting units 1200 in at least three colors, and the repeating unit 120 is located on a side of the drive circuit region 111 facing away from the substrate 10.

The display panel 1 provided in the present application includes a substrate 10, a pixel circuit layer 11, and a light-emitting layer 12. The pixel circuit layer 11 includes a drive circuit region 111, a first wire region 112, and a second wire region 113. The light-emitting layer 12 includes a plurality of repeating units 120. The repeating unit 120 includes light-emitting units 1200 in at least three colors.

The drive circuit region 111 includes a plurality of drive circuits configured to drive the light-emitting units 1200 to emit light. Each drive circuit is electrically connected to at least one light-emitting unit 1200, to drive the light-emitting unit 1200 to emit light. Optionally, the drive circuit region 111 at least partially overlaps, for example, coincides, with the light-emitting region. A relationship between the drive circuit region 111 and the repeating unit 120 is not limited in the embodiments of the present application. Optionally, the drive circuit region 111 is in one-to-one, or one-to-many, or many-to-one correspondence to the repeating unit 120.

The first wire region 112 and the second wire region 113 each include a plurality of wires 110. Optionally, adjacent drive circuit regions 111 along the first direction x are connected through the wires 110 located in the first wire region 112, and adjacent drive circuit regions 111 along the second direction y are connected through the wires 110 arranged in the second wire region 113.

The wires 110 in the first wire region 112 may be stacked along the direction perpendicular to the substrate 10, so that orthographic projections of the wires 110 in the first wire region 112 on the substrate 10 at least partially overlap, making an orthographic projection area of the first wire region 112 on the substrate 10 smaller. The wires 110 in the second wire region 113 may be stacked along the direction perpendicular to the substrate 10, so that orthographic projections of the wires 110 in the second wire region 113 on the substrate 10 at least partially overlap, making an orthographic projection area of the second wire region 113 on the substrate 10 smaller. Then, an area of a portion of the display panel 1 that is not blocked by the first wire region 112, the second wire region 113, and the drive circuit region 111 can be increased, that is, an area of the second region A2 is increased, thereby increasing the light transmittance of the display panel 1.

In the above implementations, as shown in FIG. 5, the display panel 1 may be a transparent display panel 1, or the display panel 1 includes a first display region AA1 and a second display region AA2, and a portion of the pixel circuit layer 11 located in the first display region AA1 includes a drive circuit region 111, a first wire region 112, and a second wire region 113, so that light transmittance of the first display region AA1 is higher than light transmittance of the second display region AA2. A photosensitive module such as a camera module or a fingerprint recognition module may be arranged below the first display region AA1. The light transmittance of the first display region AA1 is higher, which can improve performance of the photosensitive module, thereby improving performance of the display panel 1.

In a feasible implementation, as shown in FIG. 6 and FIG. 7A, the plurality of wires 110 include one or more of a data line Data, at least one scan signal line Scan, at least one reset signal line Vref, at least one light-emitting signal line EM, at least one first power signal line ELVSS, and at least one second power signal line ELVDD.

Specifically, the pixel circuit in the drive circuit region 111 may be a 7T1C circuit, an 8T1C circuit, or other circuits, which is not particularly limited in the present application. The present application is illustrated only with the 7T1C circuit and the 8T1C circuit as examples. One pixel circuit may drive one light-emitting unit 1200 or a plurality of light-emitting units 1200. The present application is illustrated only based on an example in which one pixel circuit may drive one light-emitting unit 1200.

Specifically, in the case of the 7T1C circuit, seven transistors may all be polysilicon semiconductor transistors, for example, P-type transistors. In the case of the 8T1C circuit, two of the eight transistors may be oxide semiconductor transistors, for example, N-type transistors, and other transistors may be polysilicon semiconductor transistors, for example, P-type transistors.

In a feasible implementation, as shown in FIG. 6, in the case of the 7T1C circuit, the first wire region 112 includes a scan signal line Scan, a reset signal line Vref, a light-emitting signal line EM, and a first power signal line ELVSS that are stacked along a direction away from the substrate 10.

In a feasible implementation, as shown in FIG. 8, the first wire region 112 further includes a second power signal line ELVDD. Optionally, the second power signal line ELVDD is arranged in a same layer as the light-emitting signal line EM.

It is to be noted that the second power signal line ELVDD may be laid out in a variety of manners. For example, the second power signal line ELVDD may tend to extend along the second direction y as a whole, or the second power signal line ELVDD may have a mesh structure, to improve reliability of signal transmission in the second power signal line ELVDD.

Further, when the second power signal line ELVDD has a mesh structure, the second power signal line ELVDD may be located partially in the first wire region 112 and partially in the second wire region 113. When the second power signal line ELVDD may tend to extend along the second direction y as a whole, the second power signal line ELVDD may be located wholly or partially in the second wire region 113. On this basis, when the second power signal line ELVDD cannot be located wholly in the second wire region 113 due to limitations of factors such as other wire layout manners and pixel arrangement manners, the second power signal line ELVDD may be located partially in the first wire region 112.

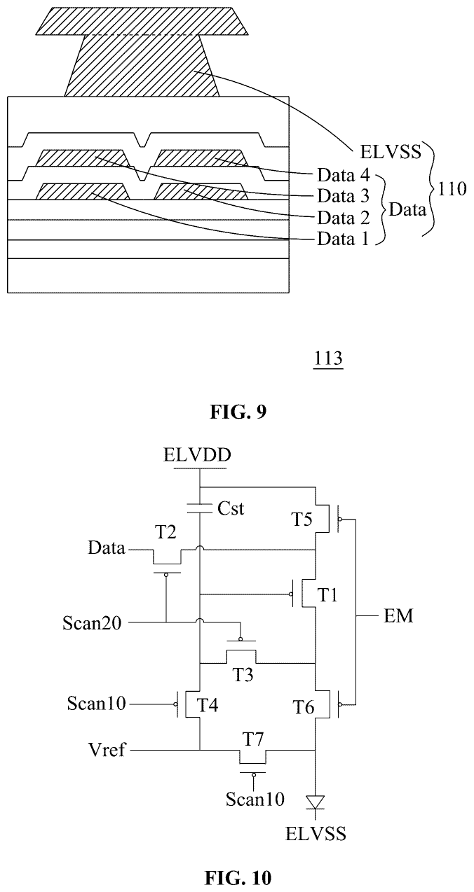

FIG. 6 and FIG. 7A illustrate a situation where the second power signal line ELVDD is not arranged in the first wire region 112 and the second power signal line ELVDD is arranged in the second wire region 113. FIG. 8 and FIG. 9 illustrate a situation where the second power signal line ELVDD is not arranged in the second wire region 113 and the second power signal line ELVDD is arranged in the first wire region 112.

Further, in the solution corresponding to FIG. 8 and FIG. 9, at the first wire region 112, due to an internal wire layout requirement of the display panel 1, the light-emitting signal line EM is required to be changed, in a manner such as through a via hole, to a film where the second power signal line ELVDD is located. As a result, at the first wire region 112, the second power signal line ELVDD is arranged in a same layer as the light-emitting signal line EM.

As shown in FIG. 7A, the second wire region 113 includes a data line Data and a first power signal line ELVSS stacked sequentially along the direction away from the substrate 10. Optionally, the first power signal line ELVSS in the first wire region 112 is electrically connected to the first power signal line ELVSS in the second wire region 113.

Optionally, one of the first power signal line ELVSS and the second power signal line ELVDD is at a high level, and the other is at a low level. For example, the first power signal line ELVSS may be a low-level signal line ELVSS, and the second power signal line ELVDD may be a high-level signal line ELVDD. The first power signal line ELVSS may be electrically connected to a second electrode (e.g., a cathode) of the light-emitting unit. The second power signal line ELVDD may be electrically connected to the pixel circuit. The pixel circuit may be electrically connected to a first electrode (e.g., an anode) of the light-emitting unit.

In the pixel circuit layer 11, the scan signal line Scan, the reset signal line Vref, and the light-emitting signal line EM extend along the first direction x, and the data line Data extends along the second direction y. Therefore, the scan signal line Scan, the reset signal line Vref, and the light-emitting signal line EM are located in the first wire region 112, and the data line Data is located in the second wire region 113.

As can be seen from the above content, in the pixel circuit layer 11, the second power signal line ELVDD may be arranged in only one of the first wire region 112 and the second wire region 113, or the second power signal line ELVDD may exist in both the first wire region 112 and the second wire region 113. For the first power signal line ELVSS, the first power signal line ELVSS may be designed in a mesh shape over the entire surface. Therefore, the first power signal line ELVSS may exist in both the first wire region 112 and the second wire region 113.

In a feasible implementation, as shown in FIG. 6 and FIG. 8, in the first wire region 112, an orthographic projection of the first power signal line ELVSS on the substrate 10 covers orthographic projections of the scan signal line Scan, the reset signal line Vref, the light-emitting signal line EM, and the second power signal line ELVDD on the substrate 10. For example, in the first wire region 112, the orthographic projection of one or more of the scan signal line Scan, the reset signal line Vref, the light-emitting signal line EM, and the second power signal line ELVDD on the substrate 10 overlaps with the orthographic projection of the first power signal line ELVSS on the substrate 10. For example, in the first wire region 112, the orthographic projection of one or more of the scan signal line Scan, the reset signal line Vref, the light-emitting signal line EM, and the second power signal line ELVDD on the substrate 10 is located within the orthographic projection of the first power signal line ELVSS on the substrate 10.

For example, in the first wire region 112, the orthographic projection of one or more of the scan signal line Scan, the reset signal line Vref, and the light-emitting signal line EM on the substrate 10 overlaps with the orthographic projection of the reset signal line Vref on the substrate 10. For example, in the first wire region 112, the orthographic projection of one or more of the scan signal line Scan, the reset signal line Vref, and the light-emitting signal line EM on the substrate 10 is located within the orthographic projection of the reset signal line Vref on the substrate 10. Through such arrangement, a shielding effect of the reset signal line Vref on the scan signal line Scan and the light-emitting signal line EM can be improved.

As shown in FIG. 7A and FIG. 9, in the second wire region 113, the orthographic projection of the first power signal line ELVSS on the substrate 10 covers the orthographic projection of the data line Data on the substrate 10.

In the above implementations, other signal lines are all arranged below the first power signal line ELVSS and covered by the first power signal line ELVSS. Firstly, the other signal lines are stacked below the first power signal line ELVSS, so that light blocking areas of the other signal lines and the first power signal line ELVSS overlap, thereby increasing an area of a blocking region of the display panel 1 that is not blocked by a film in the pixel circuit layer 11, and increasing the light transmittance. Secondly, a shielding effect can be improved. In the display panel 1, other conductive layers may also be arranged on a side of the light-emitting layer 12 away from the pixel circuit layer 11, and the first power signal line ELVSS can achieve a shielding effect on signal lines in the pixel circuit layer 11 and signal lines in the other conductive layers. Thirdly, uniformity of the display panel 1 can be improved, and only reflection of evenly distributed first power signal lines ELVSS exists.

In a feasible implementation, as shown in FIG. 6, in the first wire region 112, the orthographic projection of the reset signal line Vref on the substrate 10 at least partially overlaps, for example, coincides, with the orthographic projection of the first power signal line ELVSS on the substrate 10.

In the above implementations, the reset signal line Vref has a constant signal and may be configured to implement a shielding function. Therefore, the reset signal line Vref can shield the scan signal line Scan and the light-emitting signal line EM, which are located on two sides of the reset signal line Vref and have alternating high and low signals, to prevent signal crosstalk. Designing the reset signal line Vref to be wider can improve the shielding effect on the signal. At the same time, the orthographic projection of the reset signal line Vref on the substrate 10 at least partially overlaps, for example, coincides, with the orthographic projection of the first power signal line ELVSS on the substrate 10, so that the reset signal line Vref can be designed to be wider without causing a new light-shielding area, that is, the light-shielding area is still a light-shielding area of the first power signal line ELVSS, thereby increasing the light transmittance.

In a feasible implementation, as shown in FIG. 6, the at least one scan signal line includes a plurality of scan signal lines, the plurality of scan signal lines include a first scan line Scan 10 and a second scan line Scan 20, the first wire region includes a plurality of the scan signal lines Scan, the plurality of scan signal lines Scan include the first scan line Scan 10 and the second scan line Scan 20, the first scan line Scan 10 and the second scan line Scan 20 are arranged in different layers, and an orthographic projection of the first scan line Scan 10 on the substrate 10 is located outside an orthographic projection of the second scan line Scan 20 on the substrate 10, that is, the orthographic projections of the first scan line Scan 10 and the second scan line Scan 20 on the substrate 10 do not overlap.

In the above implementations, the first scan line Scan 10 and the second scan line Scan 20 are arranged in different layers, which, on the one hand, can facilitate wiring, and on the other hand, can reduce mutual crosstalk therebetween.

In the above implementations, the orthographic projections of the first scan line Scan 10 and the second scan line Scan 20 on the substrate 10 do not overlap, which can increase a minimum distance therebetween, thereby further reducing the crosstalk therebetween.

In the above implementations, an interval between the orthographic projections of the first scan line Scan 10 and the second scan line Scan 20 on the substrate 10 is greater than or equal to 0.5 μm and less than or equal to 2.5 μm. When an interval between the first scan line Scan 10 and the second scan line Scan 20 is within the above range, on the one hand, a definite spacing can be maintained therebetween, thereby reducing crosstalk therebetween; and on the other hand, the spacing therebetween may not be excessively large, to prevent an influence on the light transmittance due to an increase in the light-shielding area. For example, the interval between the orthographic projections of the first scan line Scan 10 and the second scan line Scan 20 on the substrate 10 can be 0.5 μm, 1 μm, 1.5 μm, 2 μm, or 2.5 μm.

Optionally, as shown in FIG. 10, the display panel includes a pixel circuit. Optionally, the pixel circuit includes some or all of first to seventh transistors T1 to T7 and a storage capacitor Cst.

Optionally, the pixel circuit includes the first transistor T1. The first transistor T1 may be a drive transistor configured to drive the light-emitting unit to emit light. The third transistor T3 is a switching transistor configured to perform threshold compensation on the first transistor T1.

Specifically, each transistor has a control terminal, a first electrode, and a second electrode, and the control terminal is configured to control conduction between the first electrode and the second electrode. The storage capacitor Cst includes a first plate and a second plate that are opposite. Optionally, the pixel circuit includes the fourth transistor T4 or the seventh transistor T7. The first scan line Scan 10 is connected to the control terminal of the fourth transistor T4. The first scan line Scan 10 is connected to the control terminal of the seventh transistor T7. The first electrode of the fourth transistor T4 is connected to the reset signal line Vref. The first electrode of the seventh transistor T7 is connected to the reset signal line Vref. The second electrode of the fourth transistor T4 is connected to the control terminal of the drive transistor and/or the second plate of the storage capacitor Cst. The second electrode of the seventh transistor T7 is connected to the first electrode (e.g., anode) of the light-emitting unit. The fourth transistor T4 is configured to reset the control terminal of the drive transistor. The seventh transistor T7 is configured to reset the first electrode of the light-emitting unit.

The second scan line Scan 20 is connected to the control terminal of the second transistor T2. The second scan line Scan 20 is connected to the control terminal of the third transistor T3. The first electrode of the second transistor T2 (which may be a data writing transistor) is connected to the data line Data, and the second electrode of the second transistor T2 is connected to the first electrode of the first transistor T1. The first electrode of the third transistor T3 (which may be a threshold compensation transistor) is connected to the control terminal of the first transistor T1. The second electrode of the third transistor T3 is connected to the second electrode of the first transistor T1. The control terminal of the first transistor T1 is connected to the second plate of the storage capacitor Cst.

The light-emitting signal line EM is connected to the control terminal of the fifth transistor T5 (which may be a first light-emitting control transistor). The light-emitting signal line EM is connected to the control terminal of the sixth transistor T6 (which may be a second light-emitting control transistor). The first electrode of the fifth transistor T5 is connected to the second power signal line ELVDD. The first plate of the storage capacitor Cst is connected to the second power signal line ELVDD. The second electrode of the fifth transistor T5 is connected to the first electrode of the first transistor T1. The first electrode of the sixth transistor T6 is connected to the second electrode of the first transistor T1, and the second electrode of the sixth transistor T6 is connected to the first electrode (e.g., anode) of the light-emitting unit. The second electrode (e.g., cathode) of the light-emitting unit is connected to the first power signal line ELVSS.

Optionally, the first transistor T1 to the seventh transistor T7 may all be P-type transistors (i.e., metal oxide semiconductor transistors), or T3 and T4 may be N-type transistors (i.e., low-temperature polysilicon semiconductor transistors), and the other transistors may all be P-type transistors.

In the above implementations, as shown in FIG. 8, in the first wire region 112, the second power signal line ELVDD is arranged in a same layer as the light-emitting signal line EM, and an interval between the second power signal line ELVDD and the light-emitting signal line EM is greater than or equal to 0.5 μm and less than or equal to 2.5 μm. When the interval between the second power signal line ELVDD and the light-emitting signal line EM is within the above range, on the one hand, a definite spacing can be maintained therebetween, thereby reducing crosstalk therebetween; and on the other hand, the spacing therebetween may not be excessively large, to prevent an influence on the light transmittance due to an increase in the light-shielding area. For example, the interval between the second power signal line ELVDD and the light-emitting signal line EM can be 0.5 μm, 1 μm, 1.5 μm, 2 μm, or 2.5 μm.

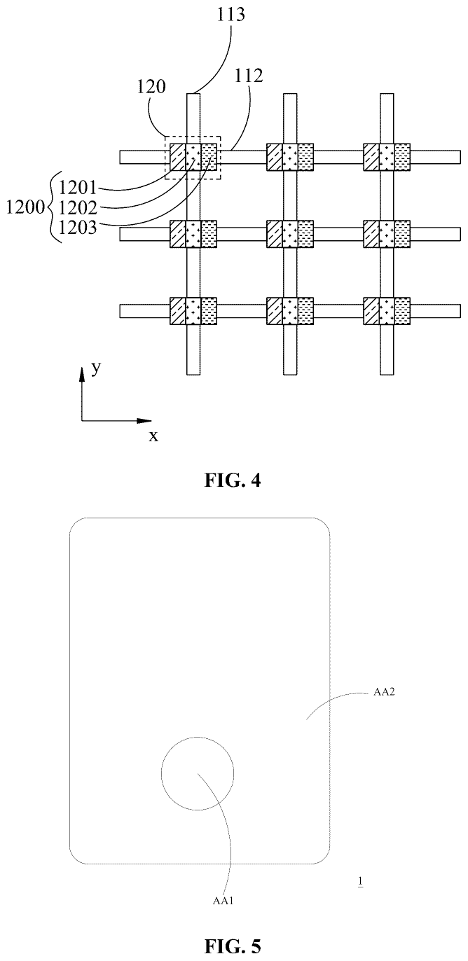

In a feasible implementation, as shown in FIG. 4, the repeating unit 120 includes a first light-emitting unit 1201, a second light-emitting unit 1202, and a third light-emitting unit 1203. The first light-emitting unit 1201, the second light-emitting unit 1202, and the third light-emitting unit 1203 emit light in different colors.

In the above implementations, the repeating unit 120 includes light-emitting units in three colors and includes three light-emitting units, which can achieve a good display effect in the case of a small number of light-emitting units. Optionally, the first light-emitting unit 1201 may be a red light-emitting unit, the second light-emitting unit 1202 may be a blue light-emitting unit, and the third light-emitting unit 1203 may be a green light-emitting unit.

It is to be noted that according to the pixel arrangement manner in FIG. 4 provided in the above implementations and on the premise of the pixel circuit layout of 7T1C, the wires 110 may be stacked in the first wire region 112 and the second wire region 113 corresponding thereto in the manner in FIG. 6 and FIG. 7A, or the wires 110 may be stacked in the first wire region 112 and the second wire region 113 corresponding thereto in the manner in FIG. 8 and FIG. 7A.

Specifically, as shown in FIG. 7A, the at least one data line includes a plurality of data lines, the plurality of data lines include a first data line Data 1, a second data line Data2, and a third data line Data3, the second wire region includes a plurality of the data lines Data, the plurality of data lines Data include the first data line Data 1, the second data line Data2, and the third data line Data3, the pixel circuit layer includes a plurality of pixel circuits, the pixel circuit connected to the first light-emitting unit 1201 is electrically connected to the first data line Data 1, the pixel circuit connected to the second light-emitting unit 1202 is electrically connected to the second data line Data2, and the pixel circuit connected to the third light-emitting unit 1203 is electrically connected to the third data line Data3.

In the above embodiments, in the second wire region 113, the first data line Data 1 and the second data line Data2 are arranged in a same layer and spaced apart, the third data line Data3 and the first data line Data 1 are arranged in different layers. As shown in FIG. 7A, FIG. 7C and FIG. 7D, the third data line Data3 is located on a side of the first data line Data 1 facing the first power signal line ELVSS, or, as shown in FIG. 7B, FIG. 7E and FIG. 7F, the third data line Data3 is located on a side of the first data line Data 1 away from the first power signal line ELVSS. Further, as shown in FIG. 7A and FIG. 7F, the second wire region 113 further includes the second power signal line ELVDD, and the second power signal line ELVDD and the third data line Data3 are arranged in a same layer and spaced apart. Alternatively, as shown in FIG. 7B and FIG. 7D, the second power signal line ELVDD is located on a side of the data line Data facing the first power signal line ELVSS, or, as shown in FIG. 7C and FIG. 7E, the second power signal line ELVDD is located on a side of the data line Data away from the first power signal line ELVSS.

The arrangement of the first data line Data 1, the second data line Data2, the third data line Data3, and the second power signal line ELVDD in two layers or three layers can enhance the space for wiring, thereby facilitating wiring and also saving the space for wiring on the premise of meeting a wiring requirement.

Further, orthographic projections of the first data line Data 1 and the third data line Data3 on the substrate 10 at least partially overlap, for example, coincide. Further, orthographic projections of the second data line Data2 and the second power signal line ELVDD on the substrate 10 at least partially overlap, for example, coincide. Therefore, on the premise of a definite line width of the first power signal line ELVSS, a width of the data line Data can be increased to reduce resistance in the data line Data. For example, the first data line Data 1 and the second data line Data2 are arranged in same layer and spaced apart.

In the above embodiments, in the second wire region 113, the orthographic projection of the first power signal line ELVSS on the substrate 10 covers the orthographic projections of the data line Data and the second power signal line ELVDD on the substrate 10. Other signal lines are all arranged below the first power signal line ELVSS and covered by the first power signal line ELVSS. On the one hand, the other signal lines are stacked below the first power signal line ELVSS, so that light blocking areas of the other signal lines and the first power signal line ELVSS overlap, thereby increasing an area of a blocking region of the display panel 1 that is not blocked by a film in the pixel circuit layer 11, and increasing the light transmittance. On the other hand, a shielding effect can be improved. In the display panel 1, other conductive layers may also be arranged on a side of the light-emitting layer 12 away from the pixel circuit layer 11, and the first power signal line ELVSS can achieve a shielding effect on signal lines in the pixel circuit layer 11 and signal lines in the other conductive layers.

In the above implementations, line widths of the first data line Data 1 and the second data line Data2 are greater than or equal to 2 μm and less than or equal to 3 μm. Therefore, on the premise of a definite wiring space, the line width of the data line Data can be made larger, thereby reducing the resistance of the data line Data. For example, the line widths of the first data line Data 1 and the second data line Data2 can be 2 μm, 2.2 μm, 2.5 μm, 2.8 μm, or 3 μm.

An interval between the first data line Data 1 and the second data line Data2 is greater than or equal to 2 μm and less than or equal to 3 μm. When the interval between the first data line Data 1 and the second data line Data2 is within the above range, on the one hand, a definite spacing can be maintained therebetween, thereby reducing crosstalk therebetween; and on the other hand, the spacing therebetween may not be excessively large, to prevent an influence on the light transmittance due to an increase in the light-shielding area. For example, the interval between the first data line Data 1 and the second data line Data2 can be 2 μm, 2.2 μm, 2.5 μm, 2.8 μm, or 3 μm.

Further, an interval between the third data line Data3 and the second power signal line ELVDD may also be greater than or equal to 2 μm and less than or equal to 3 μm. When the interval between the third data line Data3 and the second power signal line ELVDD is within the above range, on the one hand, a definite spacing can be maintained therebetween, thereby reducing crosstalk therebetween; and on the other hand, the spacing therebetween may not be excessively large, to prevent an influence on the light transmittance due to an increase in the light-shielding area. For example, the interval between the third data line Data3 and the second power signal line ELVDD can be 2 μm, 2.2 μm, 2.5 μm, 2.8 μm, or 3 μm.

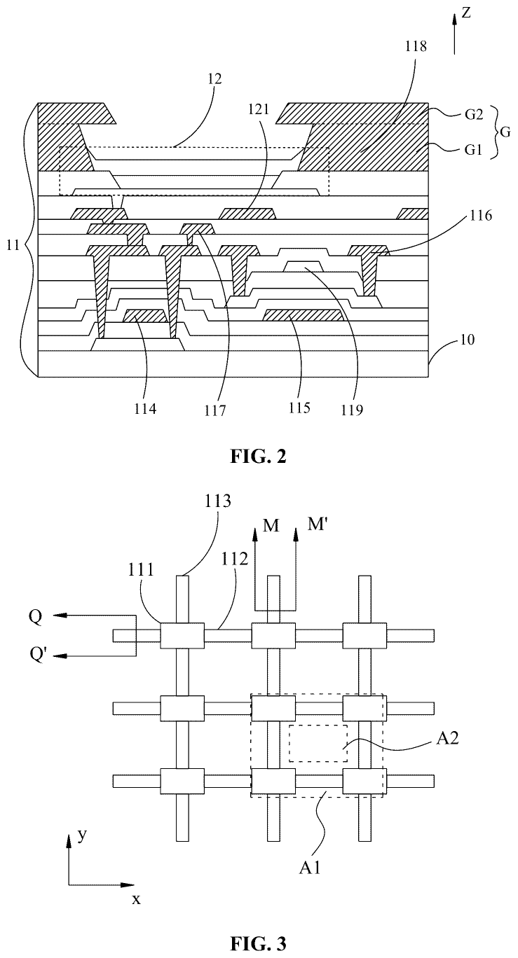

In a feasible implementation, as shown in FIG. 2, and FIG. 6, the pixel circuit layer 11 includes a first conductive layer 114, a second conductive layer 115, a third conductive layer 116, a fourth conductive layer 117, and a fifth conductive layer 118 stacked sequentially along the direction away from the substrate 10. In the first wire region 112, the first scan line Scan 10 is formed in the first conductive layer 114; the second scan line Scan 20 is formed in the second conductive layer 115; the reset signal line Vref is formed in the third conductive layer 116; the light-emitting signal line EM is formed in the fourth conductive layer 117; and the first power signal line ELVSS is formed in the fifth conductive layer 118.

In a feasible implementation, as shown in FIG. 7A to FIG. 7F, in the second wire region 113, the first data line Data 1 and the second data line Data2 are formed in the third conductive layer 116, the second power signal line ELVDD and the third data line Data3 are formed in the fourth conductive layer 117; and the first power signal line ELVSS is formed in the fifth conductive layer 118. Alternatively, the first data line Data 1 and the second data line Data2 are formed in the fourth conductive layer 117, and the second power signal line ELVDD and the third data line Data3 are formed in the third conductive layer 116. Alternatively, the first data line Data 1 and the second data line Data2 are formed in the third conductive layer 116, the third data line Data3 is formed in the fourth conductive layer 117, and the second power signal line ELVDD is formed in the second conductive layer 115. Alternatively, the first data line Data 1 and the second data line Data2 are formed in the fourth conductive layer 117, the third data line Data3 is formed in the third conductive layer 116, and the second power signal line ELVDD is formed in the second conductive layer 115.

In the above implementations, as shown in FIG. 2, in the drive circuit region 111 or the second display region AA2, the first conductive layer 114 is configured to form the gate of the transistor, the second conductive layer 115 is configured to form the first plate of the storage capacitor Cst, the third conductive layer 116 is configured to form the source and the drain of the transistor, the fourth conductive layer 117 is configured to form the wire 110, and the fifth conductive layer 118 is configured to form an isolation structure. The second plate of the storage capacitor Cst may be located in the first conductive layer 114.

In the above implementations, the third conductive layer 116 includes a titanium metal layer, an aluminum metal layer, and a titanium metal layer stacked sequentially along the direction away from the substrate 10; and the fourth conductive layer 117 includes a titanium metal layer, an aluminum metal layer, and a titanium metal layer that are stacked along the direction away from the substrate 10.

In the above implementations, as shown in FIG. 8, in the first wire region 112, the second power signal line ELVDD and the third data line Data3 are formed in the fourth conductive layer 117, that is, the second power signal line ELVDD may have a mesh structure, as shown in FIG. 7A and FIG. 8. The first power signal line ELVSS in the first wire region 112 is electrically connected to the first power signal line ELVSS in the second wire region 113.

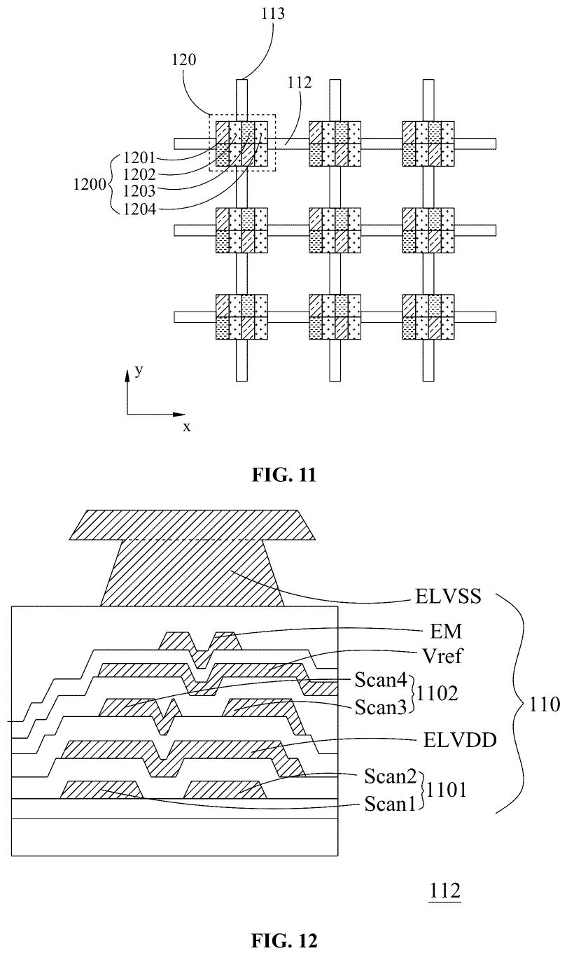

In a feasible implementation, as shown in FIG. 11, the repeating unit 120 includes one or more subunits arranged along the second direction y. Optionally, each subunit includes a first light-emitting unit 1201, a second light-emitting unit 1202, a third light-emitting unit 1203, and a fourth light-emitting unit 1204. The first light-emitting unit 1201, the second light-emitting unit 1202, and the third light-emitting unit 1203 emit light in different colors, and the second light-emitting unit 1202 and the fourth light-emitting unit 1204 emit light in a same color.

In the above implementations, one repeating unit 120 may include two subunits. That is, one repeating unit 120 may include eight light-emitting units. Each subunit includes four light-emitting units. Specifically, the four light-emitting units may be arranged along the first direction x. The subunit includes a first light-emitting unit 1201, a second light-emitting unit 1202, a third light-emitting unit 1203, and a fourth light-emitting unit 1204 that are arranged along the first direction x. The first light-emitting unit 1201 may be a red light-emitting unit, the second light-emitting unit 1202 may be a green light-emitting unit, the third light-emitting unit 1203 may be a blue light-emitting unit, and the fourth light-emitting unit 1204 may be a green light-emitting unit. Each subunit may form 4 white points through reuse of the light-emitting unit, thereby improving the display effect.

The light-emitting units may be arranged in different orders in the two subunits. Specifically, the repeating unit 120 includes a first subunit and a second subunit arranged along the second direction y, the light-emitting layer includes a plurality of first light-emitting units, a plurality of first light-emitting units, a plurality of third light-emitting units, and a plurality of fourth light-emitting units, the first subunit includes the first light-emitting unit 1201, the second light-emitting unit 1202, the third light-emitting unit 1203, and the fourth light-emitting unit 1204 arranged sequentially along the first direction x, and the second subunit includes the third light-emitting unit 1203, the second light-emitting unit 1202, a first light-emitting unit 1201, and the fourth light-emitting unit 1204 arranged sequentially along the first direction x, so that the first light-emitting unit 1201 and the third light-emitting unit 1203 are arranged oppositely along the second direction y, which can improve a light mixing effect.

In a feasible implementation, as shown in FIG. 9 and FIG. 11, the at least one data line includes a plurality of data lines, the plurality of data lines include a first data line Data 1, a second data line Data2, a third data line Data3 and a fourth data line Data4, in the second wire region 113, the plurality of data lines Data include the first data line Data 1, the second data line Data2, the third data line Data3, and the fourth data line Data4, the first data line Data 1 and the second data line Data2 are arranged in a same layer and spaced apart, the third data line Data3 and the fourth data line Data4 are arranged in a same layer and spaced apart, and the third data line Data3 is located on a side of the first data line Data 1 facing the first power signal line ELVSS.

According to different arrangement manners of pixels inside the display panel 1, four data lines may be arranged in the second wire region 113. The four data lines are configured to connect different light-emitting units respectively to achieve drive control over the different light-emitting units.

Specifically, the arrangement of the first data line Data 1, the second data line Data2, the third data line Data3, and the fourth data line Data4 in two layers can enhance the space for wiring, thereby facilitating wiring and also saving the space for wiring on the premise of meeting a wiring requirement.

In the above implementations, orthographic projections of the first data line Data 1 and the third data line Data3 on the substrate 10 at least partially overlap, for example, coincide, and orthographic projections of the second data line Data2 and the fourth data line Data4 on the substrate 10 at least partially overlap, for example, coincide. Therefore, on the premise of a definite line width of the first power signal line ELVSS, a width of the data line Data can be increased to reduce resistance in the data line Data.

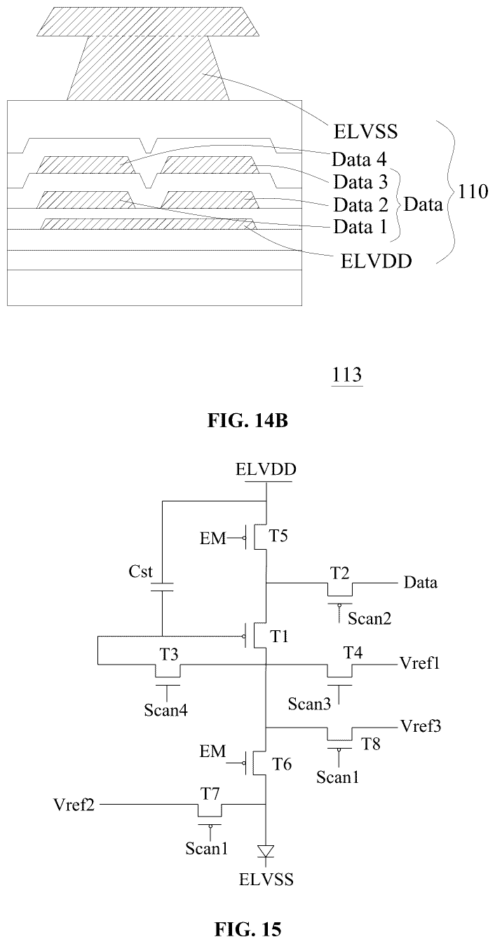

In some embodiments, the second wire region 113 further includes the second power signal line ELVDD, as shown in FIG. 14A, in the second wire region 113, the second power signal line ELVDD is located on a side of the third data line Data3 facing the first power signal line ELVSS. Alternatively, as shown in FIG. 14B, in the second wire region 113, the second power signal line ELVDD is located on a side of the first data line Data 1 away from the first power signal line ELVSS.

Optionally, in the second wire region 113, the second power signal line ELVDD is located between the first data line Data 1 and the third data line Data3.

In a feasible implementation, a pixel circuit connected to a first column of light-emitting units of the repeating unit 120 is electrically connected to the first data line Data 1, a pixel circuit connected to a second column of light-emitting units of the repeating unit 120 is electrically connected to the second data line Data2, a pixel circuit connected to a third column of light-emitting units of the repeating unit 120 is electrically connected to the third data line Data3, a pixel circuit connected to a fourth column of light-emitting units of the repeating unit 120 is electrically connected to the fourth data line Data4, and the second direction y is parallel to a column direction.

Four columns of light-emitting units may be arranged in a single repeating unit 120. A number of the light-emitting units in each column generally depends on a number of subunits in the repeating unit 120. For example, if two subunits are arranged in a single repeating unit 120, each column in the single repeating unit 120 may include two light-emitting units. Further, a number of data lines Data corresponding to a single repeating unit 120 is four, and the four data lines Data are respectively arranged corresponding to the pixel circuits connected to the light-emitting units in different columns.

Further, a single subunit includes four light-emitting units, the four light-emitting units are respectively connected to different data lines Data, and the four data lines Data respectively perform drive control over the pixel circuits connected to the different light-emitting units in the single subunit. It is to be noted that different subunits are arranged side by side in the second direction y, and the pixel circuits connected to adjacent light-emitting units in different subunits in the second direction y may be connected to a same data line Data, so that the same data line Data may perform simultaneous control over the pixel circuits connected to a plurality of light-emitting units arranged in the second direction y.

In the above implementations, line widths of the first data line Data 1 and the second data line Data2 are greater than or equal to 2 μm and less than or equal to 3 μm. Therefore, on the premise of a definite wiring space, the line width of the data line Data can be made larger, thereby reducing the resistance of the data line Data. An interval between the first data line Data 1 and the second data line Data2 is greater than or equal to 2 μm and less than or equal to 3 μm. When the interval between the first data line Data 1 and the second data line Data2 is within the above range, on the one hand, a definite spacing can be maintained therebetween, thereby reducing crosstalk therebetween; and on the other hand, the spacing therebetween may not be excessively large, to prevent an influence on the light transmittance due to an increase in the light-shielding area. Optionally, an interval between the third data line Data3 and the fourth data line Data4 is greater than or equal to 2 μm and less than or equal to 3 μm. When the interval between the third data line Data3 and the fourth data line Data4 is within the above range, on the one hand, a definite spacing can be maintained therebetween, thereby reducing crosstalk therebetween; and on the other hand, the spacing therebetween may not be excessively large, to prevent an influence on the light transmittance due to an increase in the light-shielding area. For example, the line widths of the first data line Data 1 and the second data line Data2 can be 2 μm, 2.2 μm, 2.5 μm, 2.8 μm, or 3 μm. For example, the interval between the first data line Data 1 and the second data line Data2 can be 2 μm, 2.2 μm, 2.5 μm, 2.8 μm, or 3 μm. For example, the interval between the third data line Data3 and the fourth data line Data4 can be 2 μm, 2.2 μm, 2.5 μm, 2.8 μm, or 3 μm.

According to the pixel arrangement manner in FIG. 11 provided in the above implementations and on the premise of the pixel circuit layout of 7T1C, the wires 110 may be stacked in the first wire region 112 and the second wire region 113 corresponding thereto in the manner in FIG. 8 and FIG. 9.

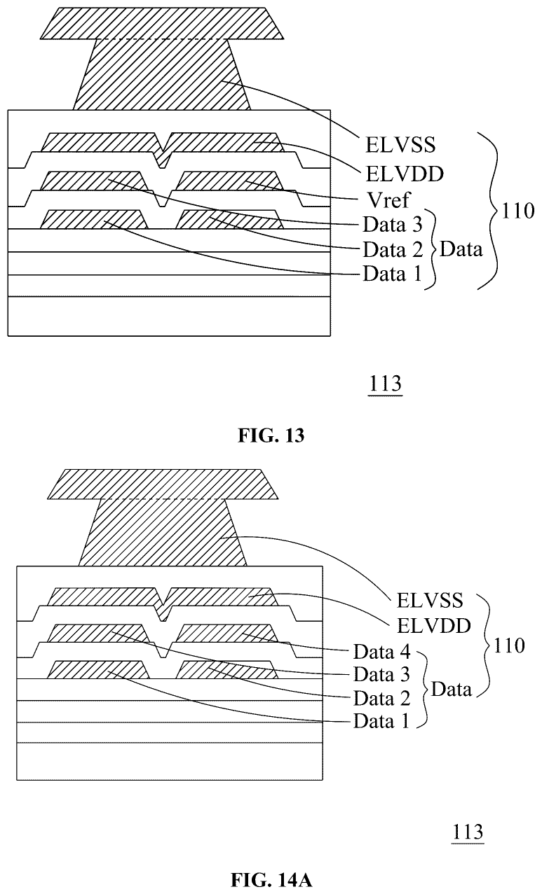

In a feasible implementation, as shown in FIG. 12 and FIG. 13, for example, in a case where the pixel circuit is an 8T1C circuit, the plurality of wires 110 include one or more of a data line Data, at least one scan signal line Scan, at least one reset signal line Vref, at least one light-emitting signal line EM, at least one first power signal line ELVSS, and at least one second power signal line ELVDD.

As shown in FIG. 12, the first wire region 112 includes a scan signal line Scan, a second power signal line ELVDD, a reset signal line Vref, a light-emitting signal line EM, and a first power signal line ELVSS that are stacked along the direction away from the substrate 10. The at least one scan signal line includes a plurality of the scan signal lines, the plurality of scan signal lines Scan include at least one first-type scan signal line 1101 and at least one second-type scan signal line 1102. The first wire region includes a plurality of the scan signal lines Scan, the plurality of scan signal lines Scan include a first-type scan signal line 1101 and a second-type scan signal line 1102 arranged in different layers, the second power signal line ELVDD is arranged between the first-type scan signal line 1101 and the second-type scan signal line 1102 along the direction perpendicular to the substrate 10, and the reset signal line Vref is arranged between the light-emitting signal line EM and the second-type scan signal line 1102 along the direction perpendicular to the substrate 10.

As shown in FIG. 13, the second wire region 113 includes a data line Data, a second power signal line ELVDD, and a first power signal line ELVSS stacked sequentially along the direction away from the substrate 10. For example, the first power signal line ELVSS in the first wire region 112 is electrically connected to the first power signal line ELVSS in the second wire region 113.

In the above implementations, the reset signal line Vref and the second power signal line ELVDD have a constant signal and may be configured to implement a shielding function. Therefore, the reset signal line Vref can shield the light-emitting signal line EM and the second-type scan signal line 1102, which are located on two sides of the reset signal line Vref and have alternating high and low signals, and the second power signal line ELVDD can shield the first-type scan signal line 1101 and the second-type scan signal line 1102, which are located on two sides of the second power signal line ELVDD and have alternating high and low signals, to prevent signal crosstalk.

In the above implementations, the first power signal line ELVSS in the first wire region 112 is electrically connected to the first power signal line ELVSS in the second wire region 113, so that the first power signal line ELVSS forms a structure in a mesh shape over an entire surface, thereby reducing the resistance.

In a feasible implementation, in the first wire region 112, an orthographic projection of the first power signal line ELVSS on the substrate 10 covers orthographic projections of the scan signal line Scan, the reset signal line Vref, and the light-emitting signal line EM on the substrate 10. For example, in the first wire region 112, the orthographic projection of one or more of the scan signal line Scan, the reset signal line Vref, and the light-emitting signal line EM on the substrate 10 overlaps with the orthographic projection of the first power signal line ELVSS on the substrate 10. For example, in the first wire region 112, the orthographic projection of one or more of the scan signal line Scan, the reset signal line Vref, and the light-emitting signal line EM on the substrate 10 is located within the orthographic projection of the first power signal line ELVSS on the substrate 10.

In the second wire region 113, the orthographic projection of the first power signal line ELVSS on the substrate 10 covers the orthographic projections of the data line Data and the second power signal line ELVDD on the substrate 10.

In the above implementations, other signal lines are all arranged below the first power signal line ELVSS and covered by the first power signal line ELVSS. Firstly, the other signal lines are stacked below the first power signal line ELVSS, so that light blocking areas of the other signal lines and the first power signal line ELVSS overlap, thereby increasing an area of a blocking region of the display panel 1 that is not blocked by a film in the pixel circuit layer 11, and increasing the light transmittance. Secondly, a shielding effect can be improved. In the display panel 1, other conductive layers may also be arranged on a side of the light-emitting layer 12 away from the pixel circuit layer 11, and the first power signal line ELVSS can achieve a shielding effect on signal lines in the pixel circuit layer 11 and signal lines in the other conductive layers. Thirdly, uniformity of the display panel 1 can be improved, and only reflection of evenly distributed first power signal lines ELVSS exists.

In a feasible implementation, as shown in FIG. 10, in the first wire region 112, the orthographic projection of the reset signal line Vref on the substrate 10 at least partially overlaps, for example, coincides, with the orthographic projection of the first power signal line ELVSS on the substrate 10.

In the above implementations, the reset signal line Vref has a constant signal and may be configured to implement a shielding function. Therefore, the reset signal line Vref can shield the scan signal line Scan and the light-emitting signal line EM, which are located on two sides of the reset signal line Vref and have alternating high and low signals, to prevent signal crosstalk. Designing the reset signal line Vref to be wider can improve the shielding effect on the signal. At the same time, the orthographic projection of the reset signal line Vref on the substrate 10 at least partially overlaps, for example, coincides, with the orthographic projection of the first power signal line ELVSS on the substrate 10, so that the reset signal line Vref can be designed to be wider without causing a new light-shielding area, that is, the light-shielding area is still a light-shielding area of the first power signal line ELVSS, thereby increasing the light transmittance.

In a feasible implementation, the second power signal line ELVDD in the first wire region 112 is electrically connected to the second power signal line ELVDD in the second wire region 113. The second power signal line ELVDD can form a structure in a mesh shape over an entire surface, so that resistance can be reduced.

In a feasible implementation, as shown in FIG. 12, the at least one first-type scan signal line includes a plurality of first-type scan signal lines 1101, the first wire region includes the plurality of first-type scan signal lines 1101, the plurality of first-type scan signal lines 1101 include a first sub-scan line Scan 1 and a second sub-scan line Scan2, the first sub-scan line Scan 1 and the second sub-scan line Scan2 are arranged in a same layer, and an orthographic projection of the first sub-scan line Scan 1 on the substrate 10 is located outside an orthographic projection of the second sub-scan line Scan2 on the substrate 10. That is, the orthographic projection of the first sub-scan line Scan1 on the substrate 10 does not overlap with the orthographic projection of the second sub-scan line Scan2 on the substrate 10. The arrangement of the first sub-scan line Scan 1 and the second sub-scan line Scan2 in the same layer can save the space for wiring. The orthographic projections of the first sub-scan line Scan 1 and the second sub-scan line Scan2 on the substrate 10 do not overlap, so the first sub-scan line Scan 1 and the second sub-scan line Scan2 are spaced apart, thereby reducing signal interference therebetween.

In a feasible implementation, as shown in FIG. 12, the at least one second-type scan signal line includes a plurality of second-type scan signal lines 1102, the first wire region includes the plurality of second-type scan signal lines 1102, the plurality of second-type scan signal lines 1102 include a third sub-scan line Scan3 and a fourth sub-scan line Scan3, the third sub-scan line Scan3 and the fourth sub-scan line Scan4 are arranged in a same layer, and an orthographic projection of the third sub-scan line Scan3 on the substrate 10 is located outside an orthographic projection of the fourth sub-scan line Scan4 on the substrate 10. That is, the orthographic projection of the third sub-scan line Scan3 on the substrate 10 does not overlap with the orthographic projection of the fourth sub-scan line Scan4 on the substrate 10. The arrangement of the third sub-scan line Scan3 and the fourth sub-scan line Scan4 in the same layer can save the space for wiring. The orthographic projections of the third sub-scan line Scan3 and the fourth sub-scan line Scan4 on the substrate 10 do not overlap, so the third sub-scan line Scan3 and the fourth sub-scan line Scan4 are spaced apart, thereby reducing signal interference therebetween.

Optionally, as shown in FIG. 15, the display panel includes a pixel circuit, and the pixel circuit includes some or all of first to eighth transistors T1 to T8 and a storage capacitor Cst.

Specifically, each transistor has a control terminal, a first electrode, and a second electrode, and the control terminal is configured to control conduction between the first electrode and the second electrode. The storage capacitor Cst includes a first plate and a second plate that are opposite. The first sub-scan line Scan 1 is connected to the control terminal of the seventh transistor T7. The first sub-scan line Scan 1 is connected to the control terminal of the eighth transistor T8. The first electrode of the seventh transistor T7 is connected to the reset signal line Vref. The second electrode of the seventh transistor T7 is connected to the first electrode of the light-emitting unit. The first electrode of the eighth transistor T8 is connected to the reset signal line Vref. The second electrode of the eighth transistor T8 is connected to the second electrode or the first electrode of the first transistor T1. The eighth transistor T8 may be configured to reset the second electrode or the first electrode of the first transistor T1.

The second sub-scan line Scan 2 is connected to the control terminal of the second transistor T2. The first electrode of the second transistor T2 is connected to the data line Data. The second electrode of the second transistor T2 is connected to the first electrode of the first transistor T1.

The third sub-scan line Scan 3 is connected to the control terminal of the fourth transistor T4, the first electrode of the fourth transistor T4 is connected to the second electrode of the first transistor T1 (as shown in FIG. 15) or the control terminal of the first transistor T1, and the second electrode of the fourth transistor T4 is connected to the reset signal line Vref.

The fourth sub-scan line Scan 4 is connected to the control terminal of the third transistor T3, the first electrode of the third transistor T3 is connected to the control terminal of the first transistor T1, and the second electrode of the third transistor T3 is connected to the second electrode of the first transistor T1.

The light-emitting signal line EM is connected to the control terminals of the fifth transistor T5 and the sixth transistor T6, and the first electrode of the fifth transistor T5 is connected to the second power signal line ELVDD. The first plate of the storage capacitor Cst is connected to the second power signal line ELVDD. The second electrode of the fifth transistor T5 is connected to the first electrode of the first transistor T1. The first electrode of the sixth transistor T6 is connected to the second electrode of the first transistor T1, and the second electrode of the sixth transistor T6 is connected to the first electrode of the light-emitting unit. The second electrode (e.g., cathode) of the light-emitting unit is connected to the first power signal line ELVSS.

Optionally, the first electrodes of the fourth transistor T4, the seventh transistor T7, and the eighth transistor T8 are all connected to the reset signal line Vref, which may be connected to different reset signal lines Vref respectively, that is, receive reset signals of different potentials. Specifically, the first electrode of the fourth transistor T4 may be connected to a reset signal Vref1, the first electrode of the seventh transistor T7 may be connected to a reset signal Vref2, and the first electrode of the eighth transistor T8 may be connected to a reset signal Vref3.

Optionally, in the eight transistors from the first transistor T1 to the eighth transistor T8, T3 and T4 are N-type transistors (i.e., low-temperature polysilicon semiconductor transistors), and the other transistors are P-type transistors (i.e., metal oxide semiconductor transistors).

In a feasible implementation, as shown in FIG. 12, in the first wire region 112, the orthographic projection of the second power signal line ELVDD on the substrate 10 at least partially overlaps, for example, coincides, with the orthographic projection of the first power signal line ELVSS on the substrate 10.

In the above implementations, the second power signal line ELVDD has a constant signal and may be configured to implement a shielding function. Therefore, the second power signal line ELVDD can shield the first-type scan signal line 1101 and the second-type scan signal line 1102, which are located on two sides of the second power signal line ELVDD and have alternating high and low signals, to prevent signal crosstalk. The second power signal line ELVDD is designed to be wider. Specifically, the second power signal line ELVDD is arranged to have a same width as the first power signal line ELVSS, which can improve the shielding effect of the second power signal line ELVDD on the signal. At the same time, the orthographic projection of the second power signal line ELVDD on the substrate 10 at least partially overlaps, for example, coincides, with the orthographic projection of the first power signal line ELVSS on the substrate 10, so that the second power signal line ELVDD can be designed to have a wider line width without causing a new light-shielding area, that is, the light-shielding area is still a light-shielding area of the first power signal line ELVSS, thereby increasing the light transmittance.

In a feasible implementation, as shown in FIG. 12, an interval between the orthographic projections of the first sub-scan line Scan 1 and the second sub-scan line Scan2 on the substrate 10 is greater than or equal to 1.5 μm and less than or equal to 2.5 μm. When an interval between the first scan line Scan 10 and the second scan line Scan 20 is within the above range, on the one hand, a definite spacing can be maintained therebetween, thereby reducing the crosstalk therebetween; and on the other hand, the spacing therebetween may not be excessively large, to prevent an influence on the light transmittance due to an increase in the light-shielding area. For example, the interval between the orthographic projections of the first sub-scan line Scan 1 and the second sub-scan line Scan2 on the substrate 10 can be 1.5 μm, 1.8 μm, 2 μm, 2.2 μm, or 2.5 μm.

In a feasible implementation, as shown in FIG. 12, an interval between the orthographic projections of the third sub-scan line Scan3 and the fourth sub-scan line Scan4 on the substrate 10 is greater than or equal to 1.5 μm and less than or equal to 2.5 μm. When an interval between the third sub-scan line and the fourth sub-scan line is within the above range, on the one hand, a definite spacing can be maintained therebetween, thereby reducing the crosstalk therebetween; and on the other hand, the spacing therebetween may not be excessively large, to prevent an influence on the light transmittance due to an increase in the light-shielding area. For example, the interval between the orthographic projections of the third sub-scan line Scan3 and the fourth sub-scan line Scan4 on the substrate 10 can be 1.5 μm, 1.8 μm, 2 μm, 2.2 μm, or 2.5 μm.

In a feasible implementation, as shown in FIG. 12, in the first wire region 112, the orthographic projections of the first-type scan signal line 1101 and the second-type scan signal line 1102 on the substrate 10 at least partially overlap. In the first wire region 112, the orthographic projections of the first-type scan signal line 1101 and the second-type scan signal line 1102 on the substrate 10 at least partially do not overlap and are misaligned.

Specifically, the first-type scan signal line 1101 is configured to connect the P-type transistor. The second-type scan signal line 1102 is configured to connect the N-type transistor. The first-type scan signal line 1101 is configured to connect the polysilicon semiconductor transistor, and the second-type scan signal line 1102 is configured to connect the oxide semiconductor transistor. The misalignment of the orthographic projections of the first-type scan signal line 1101 and the second-type scan signal line 1102 on the substrate 10 can increase a minimum distance therebetween, thereby further reducing the interference.

In a feasible implementation, as shown in FIG. 4, FIG. 12, and FIG. 13, the repeating unit 120 includes a first light-emitting unit 1201, a second light-emitting unit 1202, and a third light-emitting unit 1203. The first light-emitting unit 1201, the second light-emitting unit 1202, and the third light-emitting unit 1203 emit light in different colors. The pixel circuit layer includes a plurality of pixel circuits. Further, the pixel circuit connected to the first light-emitting unit 1201 is electrically connected to the first data line Data 1, the pixel circuit connected to the second light-emitting unit 1202 is electrically connected to the second data line Data2, and the pixel circuit connected to the third light-emitting unit 1203 is electrically connected to the third data line Data3.

For example, FIG. 12, and FIG. 13 show the pixel arrangement manner provided in FIG. 4 according to the embodiments of the present application and the stacking manner of the plurality of wires 110 corresponding to the first wire region 112 and the second wire region 113 when the pixel circuit is an 8T1C circuit.

Specifically, as shown in FIG. 13, the plurality of data lines Data include a first data line Data 1, a second data line Data2, and a third data line Data3, the first data line Data 1 and the second data line Data2 are arranged in same layer and spaced apart, the third data line Data3 is located on a side of the first data line Data 1 facing the first power signal line ELVSS, the second wire region 113 further includes a reset signal line Vref, and the reset signal line Vref and the third data line Data3 are arranged in a same layer and spaced apart.

Specifically, the arrangement of the first data line Data 1, the second data line Data2, the third data line Data3, and the reset signal line Vref in two layers can enhance the space for wiring, thereby facilitating wiring and also saving the space for wiring on the premise of meeting a wiring requirement.

In the above implementations, orthographic projections of the first data line Data 1 and the third data line Data3 on the substrate 10 at least partially overlap, for example, coincide, and orthographic projections of the second data line Data2 and the reset signal line Vref on the substrate 10 at least partially overlap, for example, coincide. Therefore, on the premise of a definite line width of the first power signal line ELVSS, a width of the data line Data can be increased to reduce resistance in the data line Data.

In the above implementations, the reset signal line Vref in the first wire region 112 is electrically connected to the reset signal line Vref in the second wire region 113, so that the reset signal line Vref forms a structure in a mesh shape over an entire surface, thereby reducing the resistance. In a feasible implementation, the reset signal line Vref in the first wire region 112 and the reset signal line Vref in the second wire region 113 are insulated and connected to different transistors in the pixel circuit.

In the above implementations, line widths of the first data line Data 1 and the second data line Data2 are greater than or equal to 2 μm and less than or equal to 3 μm. Therefore, on the premise of a definite wiring space, the line width of the data line Data can be made larger, thereby reducing the resistance of the data line Data. An interval between the first data line Data 1 and the second data line Data2 is greater than or equal to 2 μm and less than or equal to 3 μm. When the spacing between the first data line Data 1 and the second data line Data2 is within the above range, on the one hand, a definite spacing can be maintained therebetween, thereby reducing crosstalk therebetween; and on the other hand, the spacing therebetween may not be excessively large, to prevent an influence on the light transmittance due to an increase in the light-shielding area. For example, an interval between the third data line Data3 and the reset signal line Vref is greater than or equal to 2 μm and less than or equal to 3 μm. When the interval between the third data line Data3 and the reset signal line Vref is within the above range, on the one hand, a definite spacing can be maintained therebetween, thereby reducing crosstalk therebetween; and on the other hand, the spacing therebetween may not be excessively large, to prevent an influence on the light transmittance due to an increase in the light-shielding area. For example, the line widths of the first data line Data 1 and the second data line Data2 can be 2 μm, 2.2 μm, 2.5 μm, 2.8 μm, or 3 μm. For example, the interval between the first data line Data 1 and the second data line Data2 can be 2 μm, 2.2 μm, 2.5 μm, 2.8 μm, or 3 μm. For example, the interval between the third data line Data3 and the reset signal line Vref can be 2 μm, 2.2 μm, 2.5 μm, 2.8 μm, or 3 μm.

In a feasible implementation, as shown in FIG. 11, FIG. 12, FIG. 14A and FIG. 14B, the repeating unit 120 includes two subunits arranged along the second direction y, each subunit includes the first light-emitting unit 1201, the second light-emitting unit 1202, the third light-emitting unit 1203, and the fourth light-emitting unit 1204. The first light-emitting unit 1201, the second light-emitting unit 1202, and the third light-emitting unit 1203 emit light in different colors, and the second light-emitting unit 1202 and the fourth light-emitting unit 1204 emit light in a same color.

In the above implementations, one repeating unit 120 may include two subunits. That is, one repeating unit 120 may include eight light-emitting units. Each subunit includes four light-emitting units. Specifically, the four light-emitting units can be arranged along the first direction x. The subunit includes a first light-emitting unit 1201, a second light-emitting unit 1202, a third light-emitting unit 1203, and a fourth light-emitting unit 1204 that are arranged along the first direction x. The first light-emitting unit 1201 may be a red light-emitting unit, the second light-emitting unit 1202 may be a green light-emitting unit, the third light-emitting unit 1203 may be a blue light-emitting unit, and the fourth light-emitting unit 1204 may be a green light-emitting unit. Each subunit may form 4 white points through reuse of the light-emitting unit, thereby improving the display effect. The light-emitting units may be arranged in different orders in the two subunits.

Optionally, the light-emitting layer includes a plurality of first light-emitting units, a plurality of first light-emitting units, a plurality of third light-emitting units, and a plurality of fourth light-emitting units, the repeating unit 120 includes a first subunit and a second subunit arranged in the second direction y, the first subunit includes the first light-emitting unit 1201, the second light-emitting unit 1202, the third light-emitting unit 1203, and the fourth light-emitting unit 1204 arranged sequentially along the first direction x, and the second subunit includes the third light-emitting unit 1203, the second light-emitting unit 1202, a first light-emitting unit 1201, and the fourth light-emitting unit 1204 arranged sequentially along the first direction x, so that the first light-emitting unit 1201 and the third light-emitting unit 1203 are arranged oppositely along the second direction y, which can improve a light mixing effect.

FIG. 12, FIG. 14A and FIG. 14B show the pixel arrangement manner provided in FIG. 11 according to the embodiments of the present application and the stacking manner of the plurality of wires 110 corresponding to the first wire region 112 and the second wire region 113 when the pixel circuit is an 8T1C circuit.

Optionally, in the second wire region 113, the plurality of data lines Data include a first data line Data 1, a second data line Data2, a third data line Data3, and a fourth data line Data4, the first data line Data 1 and the second data line Data2 are arranged in a same layer and spaced apart, the third data line Data3 and the fourth data line Data4 are arranged in a same layer and spaced apart, and the third data line Data3 is located on a side of the first data line Data 1 facing the first power signal line ELVSS.

According to different arrangement manners of pixels inside the display panel 1, four data lines may be arranged in the second wire region 113. The four data lines are configured to correspond to different light-emitting units respectively to achieve drive control over the different light-emitting units.

In the above implementations, the arrangement of the first data line Data 1, the second data line Data2, the third data line Data3, and the fourth data line Data4 in two layers can enhance the space for wiring, thereby facilitating wiring and also saving the space for wiring on the premise of meeting a wiring requirement.

In the above implementations, orthographic projections of the first data line Data 1 and the third data line Data3 on the substrate 10 at least partially overlap, for example, coincide, and orthographic projections of the second data line Data2 and the fourth data line Data4 on the substrate 10 at least partially overlap, for example, coincide. Therefore, on the premise of a definite line width of the first power signal line ELVSS, a width of the data line Data can be increased to reduce resistance in the data line Data.

In a feasible implementation, the pixel circuit layer includes a plurality of pixel circuits, the pixel circuit connected to a first column of light-emitting units of the repeating unit 120 is electrically connected to the first data line Data 1, the pixel circuit connected to a second column of light-emitting units of the repeating unit 120 is electrically connected to the second data line Data2, the pixel circuit connected to a third column of light-emitting units of the repeating unit 120 is electrically connected to the third data line Data3, the pixel circuit connected to a fourth column of light-emitting units of the repeating unit 120 is electrically connected to the fourth data line Data4, and the second direction y is parallel to a column direction.

Four columns of light-emitting units may be arranged in a single repeating unit 120. A number of the light-emitting units in each column generally depends on a number of subunits in the repeating unit 120. For example, if two subunits are arranged in a single repeating unit 120, each column in the single repeating unit 120 may include two light-emitting units. Further, a number of data lines Data corresponding to a single repeating unit 120 is four, and the four data lines Data are respectively arranged corresponding to the pixel circuits connected to the light-emitting units in different columns.

Further, a single subunit includes four light-emitting units, pixel circuits connected to the four light-emitting units are respectively connected to different data lines, and the four data lines respectively perform drive control over the pixel circuits connected to the different light-emitting units in the single subunit. It is to be noted that different subunits are arranged side by side in the second direction y, and the pixel circuits connected to adjacent light-emitting units in different subunits in the second direction y may be connected to a same data line, so that the same data line may perform simultaneous control over the pixel circuits connected to a plurality of light-emitting units arranged in the second direction y.

In the above implementations, line widths of the first data line Data 1 and the second data line Data2 are greater than or equal to 2 μm and less than or equal to 3 μm. Therefore, on the premise of a definite wiring space, the line width of the data line Data can be made larger, thereby reducing the resistance of the data line Data. An interval between the first data line Data 1 and the second data line Data2 is greater than or equal to 2 μm and less than or equal to 3 μm. When the interval between the first data line Data 1 and the second data line Data2 is within the above range, on the one hand, a definite spacing can be maintained therebetween, thereby reducing crosstalk therebetween; and on the other hand, the spacing therebetween may not be excessively large, to prevent an influence on the light transmittance due to an increase in the light-shielding area. For example, an interval between the third data line Data3 and the fourth data line Data4 is greater than or equal to 2 μm and less than or equal to 3 μm. When the interval between the third data line Data3 and the fourth data line Data4 is within the above range, on the one hand, a definite spacing can be maintained therebetween, thereby reducing crosstalk therebetween; and on the other hand, the spacing therebetween may not be excessively large, to prevent an influence on the light transmittance due to an increase in the light-shielding area. For example, the line widths of the first data line Data 1 and the second data line Data2 can be 2 μm, 2.2 μm, 2.5 μm, 2.8 μm, or 3 μm. For example, the interval between the first data line Data 1 and the second data line Data2 can be 2 μm, 2.2 μm, 2.5 μm, 2.8 μm, or 3 μm. For example, the interval between the third data line Data3 and the fourth data line Data4 can be 2 μm, 2.2 μm, 2.5 μm, 2.8 μm, or 3 μm.

In a feasible implementation, as shown in FIG. 2, the pixel circuit layer 11 includes a first conductive layer 114, a second conductive layer 115, a sixth conductive layer 119, a third conductive layer 116, a fourth conductive layer 117, a seventh conductive layer 121, and a fifth conductive layer 118 stacked sequentially along the direction away from the substrate 10.

In the first wire region 112, the first-type scan signal line 1101 is formed in the first conductive layer 114; the second power signal line ELVDD is formed in the second conductive layer 115; the second-type scan signal line 1102 is formed in the sixth conductive layer 119; the reset signal line Vref is formed in the third conductive layer 116; the light-emitting signal line EM is formed in the fourth conductive layer 117; and the first power signal line ELVSS is formed in the fifth conductive layer 118.

In the second wire region 113, the second power signal line ELVDD is formed in the seventh conductive layer 121, the first data line Data 1 and the second data line Data2 are formed in the third conductive layer 116, and the third data line Data3 is formed in the fourth conductive layer 117.

In the above implementations, in the drive circuit region 111 and/or the second display region AA2, the first conductive layer 114 is configured to form the gate of the transistor (e.g., the polysilicon semiconductor transistor), the second conductive layer 115 is configured to form a bottom gate of the transistor (e.g., the oxide semiconductor transistor), the third conductive layer 116 is configured to form the source and the drain of the transistor, the fourth conductive layer 117 is configured to form the wire 110, and the fifth conductive layer 118 is configured to form an isolation structure. The sixth conductive layer 119 is configured to form a top gate of the oxide semiconductor transistor. The seventh conductive layer 121 is configured to form the wire 110. An insulating layer may be arranged between adjacent conductive layers. The conductive layer may include a metal layer, an indium tin oxide layer, or the like.

Specifically, the fifth conductive layer 118 may be formed on a side of the light-emitting layer 12 facing away from the substrate 10, for example, configured to transmit a first low-level signal, and therefore may also serve as part of the pixel circuit layer 11. Specifically, the fifth conductive layer 118 may include a titanium metal layer, an aluminum metal layer, and a titanium metal layer that are stacked along the direction away from the substrate 10. The fifth conductive layer 118 may include a first isolation portion and a second isolation portion that are stacked along the direction away from the substrate 10, and an orthographic projection of the first isolation portion on the substrate 10 is located inside the orthographic projection of the second isolation portion on the substrate 10.

Optionally, the light-emitting unit 1200 includes a first electrode, a light-emitting functional layer, and a second electrode that are stacked along the direction away from the substrate 10. The second electrode may be electrically connected to the isolation structure. A step portion is formed between the first isolation portion and the second isolation portion, so as to isolate the light-emitting functional layer from the second electrode in the light-emitting unit 1200. Therefore, different light-emitting units 1200 are independent of each other, so as to ameliorate crosstalk between adjacent light-emitting units 1200 and enhance the display effect. Moreover, adjacent light-emitting units 1200 are independent of each other and may be packaged independently, so as to increase a packaging yield. At the same time, due to the existence of the isolation structure, the light-emitting functional layer and the second electrode in the light-emitting unit 1200 in each color in the display panel 1 can be manufactured on an entire surface and then patterned, thereby eliminating a mask and saving a manufacturing cost of the display panel 1.

Specifically, the third conductive layer 116 includes a titanium metal layer, an aluminum metal layer, and a titanium metal layer that are stacked along the direction away from the substrate 10; and the fourth conductive layer 117 includes a titanium metal layer, an aluminum metal layer, and a titanium metal layer that are stacked along the direction away from the substrate 10. The sixth conductive layer 119 may be made of titanium or molybdenum.

In a feasible implementation, as shown in FIG. 2, the display panel further includes an isolation structure G, the isolation structure G includes a first isolation portion G1 and a second isolation portion G2 stacked sequentially along the direction away from the substrate 10, an orthographic projection of the first isolation portion G1 on the substrate 10 is located within an orthographic projection of the second isolation portion G2 on the substrate 10, and an area of the orthographic projection of the first isolation portion G1 on the substrate 10 is smaller than an area of the orthographic projection of the second isolation portion G2 on the substrate 10. For example, the isolation structure G may have a T-shaped cross section.

Patent PCT/CN2023/134518, Patent 202310759370.2, Patent 202310740412.8, Patent 202310707209.0, and Patent 202311346196.5 describe relevant technical solutions of the isolation structure G, the contents of which are incorporated into the present application for reference. Details are not described in this embodiment. The isolation structure G is enclosed to form a plurality of isolation openings. The arrangement of the isolation structure can form a plurality of spaced light-emitting units in different colors and second electrodes corresponding to the light-emitting units without any fine metal mask, thereby reducing the manufacturing cost of the display panel.

Optionally, the wires include the first power signal line ELVSS, and at least part of the isolation structure is reused as the first power signal line ELVSS. Optionally, the first isolation portion is reused as the first power signal line ELVSS.

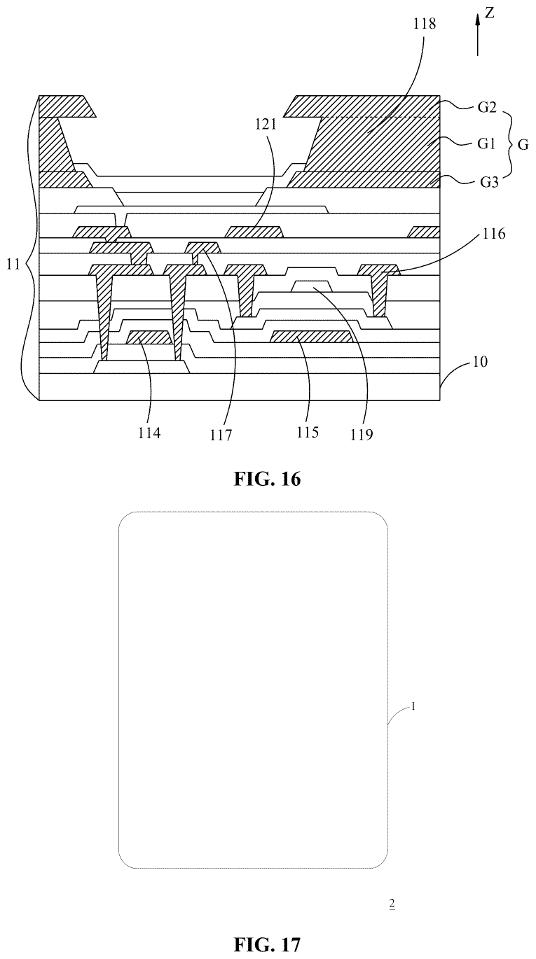

Further optionally, as shown in FIG. 16, the isolation structure G includes a third isolation portion G3 located between the substrate 10 and the first isolation portion G1; and the orthographic projection of the first isolation portion G1 on the substrate 10 is located within an orthographic projection of the third isolation portion G3 on the substrate 10, and an area of the orthographic projection of the first isolation portion G1 on the substrate 10 is smaller than an area of the orthographic projection of the third isolation portion G3 on the substrate 10. For example, the isolation structure G may have an I-shaped cross section. In the first wire region or the second wire region, at least one of the first isolation portion, the second isolation portion G2, and the third isolation portion G3 may be reused as the first power signal line ELVSS.

In the above solution, the light-emitting region includes a plurality of light-emitting units, and at least part of the isolation structure G is located between the light-emitting units.

In the above solution, the light-emitting unit includes a first electrode (e.g., an anode), a light-emitting functional layer, and a second electrode (e.g., a cathode) that are stacked along the direction away from the substrate 10, and the second electrode is electrically connected to the isolation structure. The first electrode and the second electrode jointly drive the light-emitting functional layer to emit light to meet a display requirement of the display panel. One of the first electrode and the second electrode of the light-emitting unit may be an anode, and the other may be a cathode.

In a second aspect, an embodiment of the present application provides a display panel 1. The display panel 1 has a first display region AA1. The first display region AA1 includes a first region A1. The display panel includes a substrate 10 and a plurality of wires 110 located on the substrate 10. The first region A1 includes at least one wire region. The at least one wire region includes at least part of the substrate and at least two of the plurality of wires located on the substrate, the at least two of the plurality of the wires 110 in the at least one wire region are stacked and insulated along a direction perpendicular to the substrate 10. The plurality of wires includes a first power signal line ELVSS and at least one of a data line Data, a scan signal line Scan, a reset signal line Vref, a light-emitting signal line EM, and a second power signal line ELVDD.

At least part of an isolation structure G is reused as the first power signal line ELVSS; in the at least one wire region, the at least part of the isolation structure G reused as the first power signal line ELVSS and the at least one of the data line Data, the scan signal line Scan, the reset signal line Vref, the light-emitting signal line EM, and the second power signal line ELVDD are stacked and insulated along the direction perpendicular to the substrate 10.

In the embodiments of the present application, because that the wires 110 in the wire region are stacked in the direction perpendicular to the substrate 10, the orthographic projections of the wires 110 in the wire region on the substrate 10 at least partially overlap, making an orthographic projection area of the wire region on the substrate 10 smaller. Then, an area of a portion of the display panel 1 that is not blocked by the wire region can be increased, thereby increasing the light transmittance of the display panel 1. Further, the at least part of the isolation structure G reused as the first power signal line ELVSS and the at least one of the data line Data, the scan signal line Scan, the reset signal line Vref, the light-emitting signal line EM, and the second power signal line ELVDD are stacked and insulated along the direction perpendicular to the substrate 10, so that with the help of the isolation structure G, a portion of the wires 110 can be blocked and the light transmittance of display panel 1 can be improved.

In some embodiments, the at least one wire region includes at least one first wire region 112, at least two of the plurality of wires 110 in the first wire region 112 are stacked along the direction perpendicular to the substrate 10, and the at least two of the plurality of wires in the first wire region 112 extend along a first direction x; in the first wire region 112, the at least part of the isolation structure G reused as the first power signal line ELVSS and the at least one of the data line Data, the scan signal line Scan, the reset signal line Vref, the light-emitting signal line EM, and the second power signal line ELVDD are stacked and insulated along the direction perpendicular to the substrate 10.

The at least one wire region includes at least one second wire region 113, at least two of the plurality of wires 110 in the second wire region 113 are stacked along the direction perpendicular to the substrate 10, and the at least two of the plurality of wires in the second wire region 113 extend along a second direction y; in the second wire region 113, the at least part of the isolation structure G reused as the first power signal line ELVSS and the at least one of the data line Data, the scan signal line Scan, the reset signal line Vref, the light-emitting signal line EM, and the second power signal line ELVDD are stacked and insulated along the direction perpendicular to the substrate 10.

In some embodiments, the first region Al further includes a plurality of light-emitting region (which may be, for example, positioned the same as a drive circuit region 111 in FIG. 3), and a plurality of light-emitting regions and a plurality of first wire regions 112 are arranged alternately in the first direction x; a plurality of light-emitting regions and a plurality of second wire regions 113 are arranged alternately in the second direction y. The first direction x intersects, for example, is perpendicular to, the second direction.

Light-emitting units may be arranged in the light-emitting region to realize a light-emitting display function. “The plurality of light-emitting regions and the plurality of first wire regions 112 are arranged alternately in the first direction x” means that two first wire regions 112 are arranged respectively on two sides of the light-emitting region in the first direction x. Further, a drive circuit configured to drive the light-emitting units to emit light and display may be correspondingly arranged at the light-emitting region, and the wires 110 in the first wire regions 112 may be electrically connected to the drive circuit, to meet light-emitting requirements of the light-emitting units.

Similarly, “the plurality of light-emitting regions and the plurality of second wire regions 113 are arranged alternately in the second direction y” means that two second wire regions 113 are arranged respectively on two sides of the light-emitting region in the second direction y. Further, a drive circuit configured to drive the light-emitting units to emit light and display may be correspondingly arranged at the light-emitting region, and the wires 110 in the second wire regions 113 may be electrically connected to the drive circuit, to meet light-emitting requirements of the light-emitting units.

In some embodiments, the first display region AA1 further includes a second region A2, and light transmittance of the first region Al is lower than light transmittance of the second region A2.

The first display region AA1 includes at least the first region Al and the second region A2, the wires are arranged in the first region A1, at least one wire region is provided, and the wires arranged in the second region A2 are reduced or canceled, so that the light transmittance of the first region A1 is lower than the light transmittance of the second region A2. Since the light transmittance of the second region A2 is higher, the photosensitive module arranged on one side of the first display region AA1 may collect or receive light passing through the second region A2. The photosensitive module may be, for example, a camera module, a fingerprint recognition module, or the like. Further optionally, the second region A2 is a non-light-emitting region, to reduce an influence of light-emitting units on the light transmittance of the second region A2, which helps improve performance accuracy of the photosensitive module.

In some embodiments, one or more of the first wire region 112, the second wire region 113, and the light-emitting region are arranged between adjacent second regions A2.

Referring to the drawings, the first wire region 112, the second wire region 113, and the light-emitting region may be enclosed to form a ring-shaped structure surrounding the second region A2. Further optionally, a plurality of second regions A2 and a plurality of first wire regions 112 are arranged alternately in the second direction y, a plurality of second regions A2 and a plurality of second wire regions 113 are arranged alternately in the first direction x.

In some embodiments, the isolation structure G includes a first isolation portion G1 and a second isolation portion G2 stacked sequentially along the direction away from the substrate 10, an orthographic projection of the first isolation portion G1 on the substrate 10 is located within an orthographic projection of the second isolation portion G2 on the substrate 10, and an area of the orthographic projection of the first isolation portion G1 on the substrate 10 is smaller than an area of the orthographic projection of the second isolation portion G2 on the substrate 10. For example, the isolation structure G may have a T-shaped cross section.

Further optionally, as shown in FIG. 16, the isolation structure G includes a third isolation portion G3 located between the substrate 10 and the first isolation portion G1; and the orthographic projection of the first isolation portion G1 on the substrate 10 is located within an orthographic projection of the third isolation portion G3 on the substrate 10, and an area of the orthographic projection of the first isolation portion G1 on the substrate 10 is smaller than an area of the orthographic projection of the third isolation portion G3 on the substrate 10. For example, the isolation structure G may have an I-shaped cross section. In the first wire region or the second wire region, at least one of the first isolation portion, the second isolation portion G2, and the third isolation portion G3 may be reused as the first power signal line ELVSS.

This embodiment may be combined with some or all of the characteristics of the above embodiments, which will not be repeated here.

In the above solution, the light-emitting region includes a plurality of light-emitting units, and at least part of the isolation structure G is located between the light-emitting units. Further, the isolation structure G encloses and forms an isolation opening, and at least part of the light-emitting unit is located in the isolation opening.

In the above solution, the light-emitting unit includes a first electrode (e.g., an anode), a light-emitting functional layer, and a second electrode (e.g., a cathode) that are stacked along the direction away from the substrate 10, and the second electrode is electrically connected to the isolation structure. The first electrode and the second electrode jointly drive the light-emitting functional layer to emit light to meet a display requirement of the display panel. One of the first electrode and the second electrode of the light-emitting unit may be an anode, and the other may be a cathode.

The present application further provides a display apparatus 2, which, as shown in FIG. 17, includes the display panel 1 provided in any of the above implementations of the present application.

Light transmittance of the display apparatus 2 is increased, so that the photosensitive module in the display apparatus 2 can better receive light, so as to improve an operational yield of the photosensitive module. The display apparatus 2 may be a mobile terminal such as a mobile phone or a notebook computer, a fixed terminal such as a television or a computer monitor, or a wearable device such as a watch, which is not particularly limited in the present application.

In a feasible implementation, the display apparatus further includes a photosensitive module, and the photosensitive module is arranged on a side opposite to a light-emitting surface of the first display region of the display panel.

In the embodiments of the present application, since at least part of the wires in the first display region are stacked along the direction perpendicular to the substrate 10, orthographic projections of the wires in the first display region on the substrate at least partially overlap, making an orthographic projection area of the first display region on the substrate smaller. Then, an area of a portion of the first display region that is not blocked by the wires can be increased, thereby increasing light transmittance of the first display region.

On this basis, through the arrangement of the photosensitive module in the first display region, a corresponding photosensitive requirement of the photosensitive module can be met, and photosensitive accuracy of the display panel can be improved.

The above specific implementations do not limit the protection scope of the present invention. It will be understood by those skilled in the art that various modifications, combinations, sub-combinations, and replacements are possible depending on design requirements and other factors. Any modifications, equivalent replacements, and improvements made within the spirit and principles of the present invention shall be included in the protection scope of the present invention.

What is claimed is:

1. A display panel, wherein the display panel comprises a first display region, the first display region comprises a first region, and the display panel comprises: a substrate and a plurality of wires located on the substrate;
the first region comprises at least one wire region, the at least one wire region comprises at least part of the substrate and at least two of the plurality of wires located on the substrate, the at least two of the plurality of wires in the at least one wire region are stacked and insulated along a direction perpendicular to the substrate.

2. The display panel of claim 1, wherein
the at least one wire region comprises at least one first wire region, at least two of the plurality of wires in the first wire region are stacked and insulated along the direction perpendicular to the substrate, and the at least two of the plurality of wires in the first wire region extend along a first direction;
the at least one wire region comprises at least one second wire region, at least two of the plurality of wires in the second wire region are stacked and insulated along the direction perpendicular to the substrate, and the at least two of the plurality of wires in the second wire region extend along a second direction; the first direction intersects the second direction.

3. The display panel of claim 2, wherein
the first region further comprises a plurality of light-emitting regions, the at least one wire region comprises a plurality of first wire regions, the plurality of light-emitting regions and the plurality of first wire regions are arranged alternately in the first direction; the at least one wire region comprises a plurality of second wire regions, the plurality of light-emitting regions and the plurality of second wire regions are arranged alternately in the second direction;
the first display region further comprises at least one second region, and light transmittance of the first region is lower than light transmittance of the second region;
one or more of the first wire region, the second wire region, and the light-emitting region are arranged between adjacent second regions;
the at least one second region comprises a plurality of second regions, the plurality of second regions and the plurality of first wire regions are arranged alternately in the second direction, the plurality of second regions and the plurality of second wire regions are arranged alternately in the first direction;
the at least one second region is a non-light-emitting region.

4. The display panel of claim 2, wherein the plurality of wires comprise at least one shielded wire and a plurality of potential change signal lines, the first wire region comprises the at least one shielded wire and the plurality of potential change signal lines, the at least one shielded wire is arranged between the potential change signal lines along the direction perpendicular to the substrate, and the at least one shielded wire comprises a reset signal line, or a power signal line, or the reset signal line and the power signal line; the plurality of potential change signal lines comprise a scan signal line or a light-emitting signal line, or the scan signal line and the light-emitting signal line;
in the first wire region, the reset signal line is arranged between the scan signal line and the light-emitting signal line along the direction perpendicular to the substrate;
in the first wire region, the plurality of scan signal lines are located in at least two conductive layers;
the plurality of wires comprise at least one second power signal line, the first wire region further comprises the second power signal line, and in the first wire region, the second power signal line is arranged between adjacent scan signal lines along the direction perpendicular to the substrate;
the plurality of wires comprise a plurality of data lines, the second wire region comprises the plurality of data lines, the plurality of data lines are located in at least two conductive layers;
in the second wire region, the plurality of data lines are stacked and insulated along the direction perpendicular to the substrate;
the plurality of wires comprise at least one first power signal line, the first wire region comprises the first power signal line, and the second wire region comprises the first power signal line, the first power signal line in the first wire region is electrically connected to the first power signal line in the second wire region; and
the first wire region comprises the second power signal line, and the second wire region comprises the second power signal line, the second power signal line in the first wire region is electrically connected to the second power signal line in the second wire region.

5. The display panel of claim 1, wherein the display panel further comprises:
a pixel circuit layer comprising a drive circuit region, a first wire region, and a second wire region located in the first region, the first wire region and the second wire region each comprising at least two of the plurality of wires, the at least two of the plurality of wires in the first wire region being stacked and insulated along the direction perpendicular to the substrate, and the at least two of the plurality of wires in the second wire region being stacked and insulated along the direction perpendicular to the substrate; and
a light-emitting layer comprising a plurality of repeating units located in the first region, the repeating unit comprising light-emitting units in at least three colors, and the repeating unit being located on a side of the drive circuit region facing away from the substrate;
adjacent drive circuit regions along a first direction are connected to each other through the wires located in the first wire region, and adjacent drive circuit regions along a second direction are connected to each other through the wires located in the second wire region, the first direction intersects the second direction; and
the repeating units are in one-to-one correspondence to the drive circuit regions.

6. The display panel of claim 5, wherein the plurality of wires comprise at least one data line, at least one scan signal line, at least one reset signal line, at least one light-emitting signal line, at least one first power signal line, and at least one second power signal line;
the first wire region comprises the scan signal line, the reset signal line, the light-emitting signal line, and the first power signal line stacked sequentially along a direction away from the substrate;
the first wire region further comprises the second power signal line, and the second power signal line is arranged in a same layer as the light-emitting signal line; and
the second wire region comprises the data line and the first power signal line stacked sequentially along the direction away from the substrate; wherein the first power signal line in the first wire region is electrically connected to the first power signal line in the second wire region;
in the first wire region, an orthographic projection of the first power signal line on the substrate covers orthographic projections of the scan signal line, the reset signal line, the light-emitting signal line, and the second power signal line on the substrate; and in the second wire region, an orthographic projection of the first power signal line on the substrate covers an orthographic projection of the data line on the substrate; and
in the first wire region, the orthographic projection of the reset signal line on the substrate overlaps with the orthographic projection of the first power signal line on the substrate.

7. The display panel of claim 6, wherein the at least one scan signal line comprises a plurality of scan signal lines, the plurality of scan signal lines comprise a first scan line and a second scan line, the first scan line and the second scan line are arranged in different layers, and an orthographic projection of the first scan line on the substrate is located outside an orthographic projection of the second scan line on the substrate;
in the first wire region, an interval between orthographic projections of the first scan line and the second scan line adjacent to each other on the substrate is greater than or equal to 0.5 μm and less than or equal to 2.5 μm; and
in the first wire region, the second power signal line and the light-emitting signal line are arranged in a same layer, and an interval between the second power signal line and the light-emitting signal line is greater than or equal to 0.5 μm and less than or equal to 2.5 μm.

8. The display panel of claim 7, wherein the at least one data line comprises a plurality of data lines, the plurality of data lines comprise a first data line, a second data line, and a third data line, in the second wire region, the first data line and the second data line are arranged in a same layer and spaced apart, the third data line and the first data line are arranged in different layers;
the third data line is located on a side of the first data line facing or away from the first power signal line;
the second wire region further comprises the second power signal line, and the second power signal line and the third data line are arranged in a same layer and spaced apart; or, the second power signal line is located on a side of the data line facing or away from the first power signal line;
orthographic projections of the first data line and the third data line on the substrate overlap, the second power signal line and the third data line are arranged in a same layer and spaced apart, and orthographic projections of the second data line and the second power signal line on the substrate overlap;
the repeating unit comprises a first light-emitting unit, a second light-emitting unit, and a third light-emitting unit, the first light-emitting unit, the second light-emitting unit, and the third light-emitting unit emit light in different colors, the pixel circuit layer comprises a plurality of pixel circuits, the pixel circuit connected to the first light-emitting unit is electrically connected to the first data line, the pixel circuit connected to the second light-emitting unit is electrically connected to the second data line, and the pixel circuit connected to the third light-emitting unit is electrically connected to the third data line;
in the second wire region, the orthographic projection of the first power signal line on the substrate covers the orthographic projections of the data line and the second power signal line on the substrate; and
line widths of the first data line and the second data line are greater than or equal to 2 μm and less than or equal to 3 μm, and an interval between the first data line and the second data line is greater than or equal to 2 μm and less than or equal to 3 μm.

9. The display panel of claim 8, wherein the pixel circuit layer comprises a first conductive layer, a second conductive layer, a third conductive layer, a fourth conductive layer, and a fifth conductive layer stacked sequentially along the direction away from the substrate, wherein:
in the first wire region, the first scan line is formed in the first conductive layer, the second scan line is formed in the second conductive layer, the reset signal line is formed in the third conductive layer, the light-emitting signal line is formed in the fourth conductive layer, and the first power signal line is formed in the fifth conductive layer; and
in the second wire region, the first data line and the second data line are formed in the third conductive layer, and the second power signal line and the third data line are formed in the fourth conductive layer; or, the first data line and the second data line are formed in the fourth conductive layer, and the second power signal line and the third data line are formed in the third conductive layer; or, the first data line and the second data line are formed in the third conductive layer, the third data line is formed in the fourth conductive layer, and the second power signal line is formed in the second conductive layer; or, the first data line and the second data line are formed in the fourth conductive layer, the third data line is formed in the third conductive layer, and the second power signal line is formed in the second conductive layer;
the third conductive layer comprises a titanium metal layer, an aluminum metal layer, and a titanium metal layer stacked sequentially along the direction away from the substrate; and
the fourth conductive layer comprises a titanium metal layer, an aluminum metal layer, and a titanium metal layer stacked sequentially along the direction away from the substrate;
in the first wire region, the second power signal line is located in the fourth conductive layer; and
the second power signal line in the first wire region is electrically connected to the second power signal line in the second wire region.

10. The display panel of claim 7, wherein the at least one data line comprises a plurality of data lines,
in the second wire region, the plurality of data lines comprise a first data line, a second data line, a third data line, and a fourth data line, the first data line and the second data line are arranged in a same layer and spaced apart, the third data line and the fourth data line are arranged in a same layer and spaced apart, and the third data line is located on a side of the first data line facing the first power signal line;
orthographic projections of the first data line and the third data line on the substrate overlap, and orthographic projections of the second data line and the fourth data line on the substrate overlap;
the second wire region further comprises the second power signal line, the second power signal line is located on a side of the third data line facing the first power signal line; or, the second power signal line is located on a side of the first data line away from the first power signal line;
the repeating unit comprises a first subunit and a second subunit arranged along the second direction, the light-emitting layer comprises a plurality of first light-emitting units, a plurality of first light-emitting units, a plurality of third light-emitting units, and a plurality of fourth light-emitting units, the first subunit comprises the first light-emitting unit, the second light-emitting unit, the third light-emitting unit, and the fourth light-emitting unit sequentially arranged along the first direction,
the second subunit comprises the third light-emitting unit, the second light-emitting unit, the first light-emitting unit, and the fourth light-emitting unit sequentially arranged along the first direction,
the first light-emitting unit, the second light-emitting unit, and the third light-emitting unit emit light in different colors, the second light-emitting unit and the forth light-emitting unit emit light in a same color, the pixel circuit layer comprises a plurality of pixel circuits, the pixel circuit connected to a first column of light-emitting units of the repeating unit is electrically connected to the first data line, the pixel circuit connected to a second column of light-emitting units of the repeating unit is electrically connected to the second data line, the pixel circuit connected to a third column of light-emitting units of the repeating unit is electrically connected to the third data line, the pixel circuit connected to a fourth column of light-emitting units of the repeating unit is electrically connected to the fourth data line, and the second direction is parallel to a column direction; and
line widths of the first data line and the second data line are greater than or equal to 2 μm and less than or equal to 3 μm, and an interval between the first data line and the second data line is greater than or equal to 2 μm and less than or equal to 3 μm.

11. The display panel of claim 5, wherein the plurality of wires comprises at least one data line, at least one scan signal line, at least one reset signal line, at least one light-emitting signal line, at least one first power signal line, and at least one second power signal line;
the first wire region comprises the scan signal line, the second power signal line, the reset signal line, the light-emitting signal line, and the first power signal line stacked sequentially along a direction away from the substrate;
the at least one scan signal line comprises a plurality of scan signal lines, the plurality of scan signal lines comprise at least one first-type scan signal line and at least one second-type scan signal line arranged in different layers, the second power signal line is arranged between the first-type scan signal line and the second-type scan signal line along the direction perpendicular to the substrate,
the reset signal line is arranged between the light-emitting signal line and the second-type scan signal line along the direction perpendicular to the substrate; and
the second wire region comprises the at least one data line, the second power signal line, and the first power signal line stacked sequentially along the direction away from the substrate;
the first power signal line in the first wire region is electrically connected to the first power signal line in the second wire region;
in the first wire region, an orthographic projection of the first power signal line on the substrate covers orthographic projections of the scan signal line, the reset signal line, the light-emitting signal line, and the second power signal line on the substrate; and
in the second wire region, the orthographic projection of the first power signal line on the substrate covers the orthographic projections of the data line and the second power signal line on the substrate;
in the first wire region, the orthographic projection of the reset signal line on the substrate overlaps with the orthographic projection of the first power signal line on the substrate; and
the second power signal line in the first wire region is electrically connected to the second power signal line in the second wire region.

12. The display panel of claim 11, wherein the at least one first-type scan signal line comprises a plurality of first-type scan signal lines, the plurality of first-type scan signal lines comprise a first sub-scan line and a second sub-scan line, the first sub-scan line and the second sub-scan line are arranged in a same layer, and an orthographic projection of the first sub-scan line on the substrate is located outside an orthographic projection of the second sub-scan line on the substrate; and
the at least one second-type scan signal line comprises a plurality of second-type scan signal lines, the plurality of second-type scan signal lines comprise a third sub-scan line and a fourth sub-scan line, the third sub-scan line and the fourth sub-scan line are arranged in a same layer, and an orthographic projection of the third sub-scan line on the substrate is located outside an orthographic projection of the fourth sub-scan line on the substrate;
in the first wire region, the orthographic projection of the second power signal line on the substrate overlaps with the orthographic projection of the first power signal line on the substrate;
an interval between the orthographic projections of the first sub-scan line and the second sub-scan line on the substrate is greater than or equal to 1.5 μm and less than or equal to 2.5 μm;
an interval between the orthographic projections of the third sub-scan line and the fourth sub-scan line on the substrate is greater than or equal to 1.5 μm and less than or equal to 2.5 μm; and
in the first wire region, orthographic projections of the first-type scan signal line and the second-type scan signal line on the substrate partially overlap.

13. The display panel of claim 12, wherein
the at least one data line comprises a plurality of data lines, the plurality of data lines comprise a first data line, a second data line, and a third data line, the first data line and the second data line are arranged in same layer and spaced apart, the third data line is located on a side of the first data line facing the first power signal line, the second wire region further comprises the reset signal line, and the reset signal line and the third data line are arranged in a same layer and spaced apart;
orthographic projections of the first data line and the third data line on the substrate overlap, and orthographic projections of the second data line and the reset signal line on the substrate overlap;
the repeating unit comprises a first light-emitting unit, a second light-emitting unit, and a third light-emitting unit, the first light-emitting unit, the second light-emitting unit, and the third light-emitting unit emit light in different colors, the pixel circuit layer comprises a plurality of pixel circuits, the pixel circuit connected to the first light-emitting unit is electrically connected to the first data line, the pixel circuit connected to the second light-emitting unit is electrically connected to the second data line, and the pixel circuit connected to the third light-emitting unit is electrically connected to the third data line; and
line widths of the first data line and the second data line are greater than or equal to 2 μm and less than or equal to 3 μm, and an interval between the first data line and the second data line is greater than or equal to 2 μm and less than or equal to 3 μm.

14. The display panel of claim 12, wherein
the at least one data line comprises a plurality of data lines, the plurality of data lines comprise a first data line, a second data line, a third data line, and a fourth data line, the first data line and the second data line are arranged in a same layer and spaced apart, the third data line and the fourth data line are arranged in a same layer and spaced apart, and the third data line is located on a side of the first data line facing the first power signal line;
orthographic projections of the first data line and the third data line on the substrate overlap, and orthographic projections of the second data line and the fourth data line on the substrate overlap;
the repeating unit comprises a first subunit and a second subunit arranged along the second direction, the light-emitting layer comprises a plurality of first light-emitting units, a plurality of first light-emitting units, a plurality of third light-emitting units, and a plurality of fourth light-emitting units, the first subunit comprises the first light-emitting unit, the second light-emitting unit, the third light-emitting unit, and the fourth light-emitting unit sequentially arranged along the first direction,
the second subunit comprises the third light-emitting unit, the second light-emitting unit, the first light-emitting unit, and the fourth light-emitting unit sequentially arranged along the first direction,
the first light-emitting unit, the second light-emitting unit and the third light-emitting unit emit light in different colors, and the second light-emitting unit and the fourth light-emitting unit emit light in a same color; and
the pixel circuit layer comprises a plurality of pixel circuits, the pixel circuit connected to a first column of light-emitting units of the repeating unit is electrically connected to the first data line, the pixel circuit connected to a second column of light-emitting units of the repeating unit is electrically connected to the second data line, the pixel circuit connected to a third column of light-emitting units of the repeating unit is electrically connected to the third data line, the pixel circuit connected to a fourth column of light-emitting units of the repeating unit is electrically connected to the fourth data line, and the second direction is parallel to a column direction; and
line widths of the first data line and the second data line are greater than or equal to 2 μm and less than or equal to 3 μm, and an interval between the first data line and the second data line is greater than or equal to 2 μm and less than or equal to 3 μm.

15. The display panel of claim 14, wherein the pixel circuit layer comprises a first conductive layer, a second conductive layer, a sixth conductive layer, a third conductive layer, a fourth conductive layer, a seventh conductive layer, and a fifth conductive layer stacked sequentially along a direction away from the substrate;
wherein: in the first wire region, the first-type scan signal line is formed in the first conductive layer, the second power signal line is formed in the second conductive layer, the second-type scan signal line is formed in the sixth conductive layer, the reset signal line is formed in the third conductive layer, the light-emitting signal line is formed in the fourth conductive layer, and the first power signal line is formed in the fifth conductive layer; and
in the second wire region, the second power signal line is formed in the seventh conductive layer, the first data line and the second data line are formed in the third conductive layer, and the third data line and the fourth data line are formed in the fourth conductive layer;
the third conductive layer comprises a titanium metal layer, an aluminum metal layer, and a titanium metal layer stacked sequentially along the direction away from the substrate; and
the fourth conductive layer comprises a titanium metal layer, an aluminum metal layer, and a titanium metal layer stacked sequentially along the direction away from the substrate.

16. The display panel of claim 4, wherein the display panel further comprises an isolation structure,
the isolation structure comprises a first isolation portion and a second isolation portion stacked sequentially along a direction away from the substrate;
an orthographic projection of the first isolation portion on the substrate is located within an orthographic projection of the second isolation portion on the substrate, and an area of the orthographic projection of the first isolation portion on the substrate is smaller than an area of the orthographic projection of the second isolation portion on the substrate;
the wires comprise the first power signal line, and at least part of the isolation structure is reused as the first power signal line;
the first isolation portion is reused as the first power signal line;
the isolation structure comprises a third isolation portion located between the substrate and the first isolation portion; and
the orthographic projection of the first isolation portion on the substrate is located within an orthographic projection of the third isolation portion on the substrate, and the area of the orthographic projection of the first isolation portion on the substrate is smaller than an area of the orthographic projection of the third isolation portion on the substrate;
the first region further comprises a plurality of light-emitting regions, the light-emitting region comprises a plurality of light-emitting units, and at least part of the isolation structure is located between the light-emitting units; and
the light-emitting unit comprises a first electrode, a light-emitting functional layer, and a second electrode that are stacked along the direction away from the substrate, and the second electrode is electrically connected to the isolation structure.

17. A display panel, wherein the display panel comprises a first display region, the first display region comprises a first region, and the display panel comprises:
a substrate and a plurality of wires located on the substrate; wherein the first region comprises at least one wire region, the at least one wire region comprises at least part of the substrate and at least two of the plurality of wires located on the substrate, the at least two of the plurality of wires in the at least one wire region are stacked and insulated along a direction perpendicular to the substrate; the plurality of wires comprises a first power signal line and at least one of a data line, a scan signal line, a reset signal line, a light-emitting signal line, and a second power signal line;
an isolation structure, wherein at least part of the isolation structure is reused as the first power signal line; in the at least one wire region, the at least part of the isolation structure reused as the first power signal line and the at least one of the data line, the scan signal line, the reset signal line, the light-emitting signal line, and the second power signal line are stacked and insulated along the direction perpendicular to the substrate.

18. The display panel of claim 17, wherein the at least one wire region comprises at least one first wire region, at least two of the plurality of wires in the first wire region are stacked and insulated along the direction perpendicular to the substrate, and the at least two of the plurality of wires in the first wire region extend along a first direction; in the first wire region, the at least part of the isolation structure reused as the first power signal line and the at least one of the data line, the scan signal line, the reset signal line, the light-emitting signal line, and the second power signal line are stacked and insulated along the direction perpendicular to the substrate;
the at least one wire region comprises at least one second wire region, at least two of the plurality of wires in the second wire region are stacked and insulated along the direction perpendicular to the substrate, and the at least two of the plurality of wires in the second wire region extend along a second direction; the first direction intersects the second direction; in the second wire region, the at least part of the isolation structure reused as the first power signal line and the at least one of the data line, the scan signal line, the reset signal line, the light-emitting signal line, and the second power signal line are stacked and insulated along the direction perpendicular to the substrate;
the first region further comprises a plurality of light-emitting regions, the at least one wire region comprises a plurality of first wire regions, the plurality of light-emitting regions and the plurality of first wire regions are arranged alternately in the first direction; the at least one wire region comprises a plurality of second wire regions, the plurality of light-emitting regions and the plurality of second wire regions are arranged alternately in the second direction;
the first display region further comprises at least one second region, and light transmittance of the first region is lower than light transmittance of the second region;
one or more of the first wire region, the second wire region, and the light-emitting region are arranged between adjacent second regions;
the at least one second region comprises a plurality of second regions, the plurality of second regions and the plurality of first wire regions are arranged alternately in the second direction, the plurality of second regions and the plurality of second wire regions are arranged alternately in the first direction;
the at least one second region is a non-light-emitting region.

19. The display panel of claim 17, wherein the isolation structure comprises a first isolation portion and a second isolation portion stacked sequentially along a direction away from the substrate;
an orthographic projection of the first isolation portion on the substrate is located within an orthographic projection of the second isolation portion on the substrate, and an area of the orthographic projection of the first isolation portion on the substrate is smaller than an area of the orthographic projection of the second isolation portion on the substrate;
the isolation structure comprises a third isolation portion located between the substrate and the first isolation portion;
the orthographic projection of the first isolation portion on the substrate is located within an orthographic projection of the third isolation portion on the substrate, and the area of the orthographic projection of the first isolation portion on the substrate is smaller than an area of the orthographic projection of the third isolation portion on the substrate;
the first region further comprises a plurality of light-emitting regions, the light-emitting region comprises a plurality of light-emitting units, and at least part of the isolation structure is located between the light-emitting units; and
the light-emitting unit comprises a first electrode, a light-emitting functional layer, and a second electrode that are stacked along the direction away from the substrate, and the second electrode is electrically connected to the isolation structure;
the isolation structure encloses and forms an isolation opening, and at least part of the light-emitting unit is located in the isolation opening.

20. A display apparatus, comprising the display panel of claim 1, wherein the display apparatus further comprises a photosensitive module, the photosensitive module is arranged on a side opposite to a light-emitting side of the first display region of the display panel.
